(19) United States
(12) Patent Application Publication
(10) Pub. No.: US 2026/0223361 A1
(43) Pub. Date: Jul. 30, 2026

(54) THREE-DIMENSIONAL SEMICONDUCTOR DEVICE AND METHOD OF FABRICATING THE SAME

(71) Applicant: SAMSUNG ELECTRONICS CO., LTD., Suwon-si (KR)

(72) Inventors: Moohyun KIM, Suwon-si (KR); Hyung Joon Kim, Suwon-si (KR); Siyeong Yang, Suwon-si (KR); Jaeho Jung, Suwon-si (KR)

(73) Assignee: SAMSUNG ELECTRONICS CO., LTD., Suwon-si (KR)

(21) Appl. No.: 19/386,646

(22) Filed: Nov. 12, 2025

(30) Foreign Application Priority Data
Jan. 24, 2025 (KR) 10-2025-0011604

(51) Int. Cl. H10B 12/00; H10D 1/68; H10D 62/40; H10D 62/60; H10D 62/83

(52) U.S. Cl. CPC H10B 12/482; H10B 12/488; H10B 12/50; H10D 1/714; H10D 62/40; H10D 62/60; H10D 62/83; H10B 12/05

(57) ABSTRACT

A three-dimensional semiconductor device may include first and second stacks adjacent to each other in a first direction on a substrate and a data storage pattern between the first and second stacks. The first stack may include a first crystalline pattern extending in the first direction on the substrate, a first word line surrounding the first crystalline pattern and extending in a second direction, and a first bit line extending in a third direction on a side surface of the first crystalline pattern. The second stack may include a second crystalline pattern extending in the first direction. The first and second crystalline patterns may be spaced apart from each other in the first direction and may have different crystalline directions from each other. The first and second directions are parallel to a top surface of the substrate and are orthogonal to each other and to the third direction.

### CROSS-REFERENCE TO RELATED APPLICATION

This application is based on and claims priority under 35 U.S.C. §119 to Korean Patent Application No. 10-2025-0011604, filed on January 24, 2025, in the Korean Intellectual Property Office, the entire contents of which are hereby incorporated by reference.

### BACKGROUND

The present disclosure relates to a three-dimensional semiconductor device and a method of fabricating the same.

Due to their small-sized, multifunctional, and/or low-cost characteristics, semiconductor devices are important elements in the electronics industry. The semiconductor devices are classified into semiconductor memory devices for storing data, semiconductor logic devices for processing data, and hybrid semiconductor devices including both memory and logic elements.

With the recent trend of high speed and low power consumption of electronic devices, semiconductor devices in the electronic devices are also required to have high operating speeds and/or low operating voltages, and in order to satisfy this requirement, it is necessary to increase an integration density of the semiconductor device. However, as the integration density of the semiconductor device increases, the semiconductor device may suffer from deteriorated electrical characteristics and low production yield. Accordingly, many studies are being conducted to improve the electrical characteristics and production yield of the semiconductor device.

### SUMMARY

Provided is a three-dimensional semiconductor device which may have improved reliability.

Further provided is a method of fabricating a three-dimensional semiconductor device which may have improved reliability.

According to an aspect of the disclosure, a three-dimensional semiconductor device includes: a first crystalline semiconductor pattern on a substrate and a second crystalline semiconductor pattern on the first crystalline semiconductor pattern, wherein each of the first crystalline semiconductor pattern and the second crystalline semiconductor pattern extends in a first direction parallel to a top surface of the substrate; a first word line on the first crystalline semiconductor pattern and a second word line on the second crystalline semiconductor pattern, wherein each of the first word line and the second word line extends in a second direction parallel to the top surface of the substrate and orthogonal to the first direction; and a bit line on a side surface of each of the first crystalline semiconductor pattern and the second crystalline semiconductor pattern, the bit line extending in a third direction perpendicular to the top surface of the substrate, wherein a crystalline direction of the first crystalline semiconductor pattern is different from a crystalline direction of the second crystalline semiconductor pattern.

According to an aspect of the disclosure, a three-dimensional semiconductor device includes: a substrate; and a cell array structure on the substrate, wherein the cell array structure includes: a plurality of crystalline semiconductor patterns arranged vertically on the substrate, wherein each crystalline semiconductor pattern of the plurality of crystalline semiconductor patterns extends in a first direction parallel to a top surface of the substrate; a plurality of word lines on the plurality of crystalline semiconductor patterns and extending in a second direction parallel to the top surface of the substrate and orthogonal to the first direction; and a bit line on first side surfaces of the plurality of crystalline semiconductor patterns, wherein the bit line extends in a third direction perpendicular to the top surface of the substrate, wherein the plurality of crystalline semiconductor patterns includes a single-crystalline semiconductor material, wherein the substrate includes a semiconductor substrate or an insulating substrate, wherein the semiconductor substrate is one of a single-crystalline semiconductor substrate, a polycrystalline semiconductor substrate, or an amorphous semiconductor substrate, and wherein a crystalline direction of the single-crystalline semiconductor substrate is different from a crystalline direction of the plurality of crystalline semiconductor patterns.

According to an aspect of the disclosure, a three-dimensional semiconductor device includes: a substrate; a first stack and a second stack e on the substrate, wherein the first stack and the second stack are adjacent to each other in a first direction parallel to a top surface of the substrate; and a data storage pattern between the first stack and the second stack, wherein the first stack includes: a first crystalline semiconductor pattern on the substrate and extending in the first direction; a first word line on the first crystalline semiconductor pattern and extending in a second direction parallel to the top surface of the substrate and orthogonal to the first direction; and a first bit line on a first side surface of the first crystalline semiconductor pattern, the first bit line extending in a third direction perpendicular to the top surface of the substrate, wherein the second stack includes a second crystalline semiconductor pattern extending in the first direction, wherein the first crystalline semiconductor pattern and the second crystalline semiconductor pattern are spaced apart from each other in the first direction, and wherein a crystalline direction of the first crystalline semiconductor pattern is different from a crystalline direction of the second crystalline semiconductor pattern.

According to an aspect of the disclosure, a method of fabricating a three-dimensional semiconductor device includes forming a preliminary stack, which includes amorphous semiconductor patterns and insulating patterns extending in a first direction parallel to a top surface of the substrate, on a substrate; forming a metal layer on a side surface of the preliminary stack; forming a metal gathering layer on an opposite side surface of the preliminary stack; and annealing the preliminary stack to crystalize the amorphous semiconductor pattern into a single-crystalline semiconductor pattern.

The method may further include forming a word line, which is provided to surround the single-crystalline semiconductor pattern and is extended in a second direction, and forming a bit line, which is placed on a side surface of the semiconductor pattern and is extended in a third direction perpendicular to the top surface of the substrate. Here, the second direction may be parallel to the top surface of the substrate and may be orthogonal to the first direction.

The crystallization of the amorphous semiconductor pattern to the single-crystalline semiconductor pattern may be performed using a metal-induced crystallization method.

The metal layer may include at least one of nickel (Ni), palladium (Pd), or aluminum (Al).

The metal gathering layer may include silicon (Si), doped with at least one element of phosphorus (P), boron (B), arsenic (As), germanium (Ge), or carbon (C) at a concentration of 25 at% or lower.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a circuit diagram schematically illustrating a three-dimensional semiconductor device according to an embodiment of the present disclosure;

FIGS. 2A, 2B, and 2C are schematic perspective views illustrating a three-dimensional semiconductor device according to an embodiment of the present disclosure;

FIG. 3 is a perspective view illustrating semiconductor patterns, word lines, bit lines, and a data storage pattern, which are included in a three-dimensional semiconductor device according to an embodiment of the present disclosure;

FIG. 4 is a plan view illustrating a three-dimensional semiconductor device according to an embodiment of the present disclosure;

FIG. 5A is a cross-sectional view corresponding to a line A-A’ of FIG. 4;

FIG. 5B is a cross-sectional view corresponding to a line B-B’ of FIG. 4;

FIG. 6 is a cross-sectional view illustrating a three-dimensional semiconductor device according to an embodiment of the present disclosure;

FIGS. 7, 8, 9, 10A, 10B, 11, 12A, 12B, 13, 14, 15, 16, 17, 18, 19, 20A, 20B, 21, 22A, 22B, 23, 24A, 24B, 25, and 26 are diagrams illustrating a method of fabricating a three-dimensional semiconductor device, according to an embodiment of the present disclosure; and

FIGS. 27 and 28 are cross-sectional views illustrating a method of fabricating a three-dimensional semiconductor device, according to an embodiment of the present disclosure.

### DETAILED DESCRIPTION

Example embodiments of the present disclosure will now be described more fully with reference to the accompanying drawings.

In the following description, like reference numerals refer to like elements throughout the specification. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

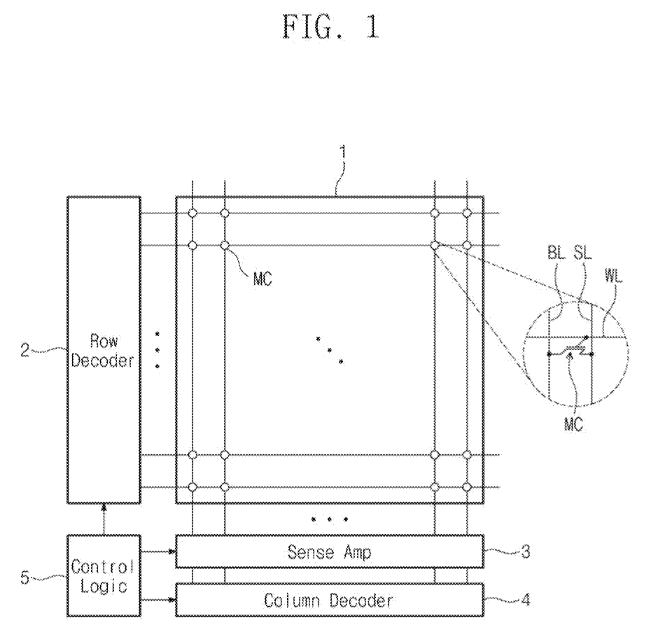

FIG. 1 is a circuit diagram schematically illustrating a three-dimensional semiconductor device according to an embodiment of the present disclosure.

Referring to FIG. 1, a three-dimensional semiconductor device may include a memory cell array 1, a row decoder 2, a sense amplifier 3, a column decoder 4, and a control logic 5.

The memory cell array 1 may include word lines WL, bit lines BL, source lines SL, and memory cells MC. The memory cells MC may be three-dimensionally arranged, and each memory cell MC may be connected to one of the word lines WL, one of the bit lines BL, and one of the source lines SL. In an embodiment, each of the memory cells MC may be composed of one transistor including a memory layer or a data storing layer.

The row decoder 2 may be configured to decode address information, which is input from the outside, and to select one of the word lines WL of the memory cell array 1, based on the decoded address information. The address information decoded by the row decoder 2 may be provided to a row driver, and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which is selected based on address information decoded by the column decoder 4, and a reference bit line.

The column decoder 4 may establish a data transmission path between the sense amplifier 3 and an external device (e.g., a memory controller). The column decoder 4 may be configured to decode address information, which is input from the outside, and to select one of the bit lines BL, based on the decoded address information.

The control logic 5 may be configured to generate control signals, which are used to control data-writing or data-reading operations on the memory cell array 1.

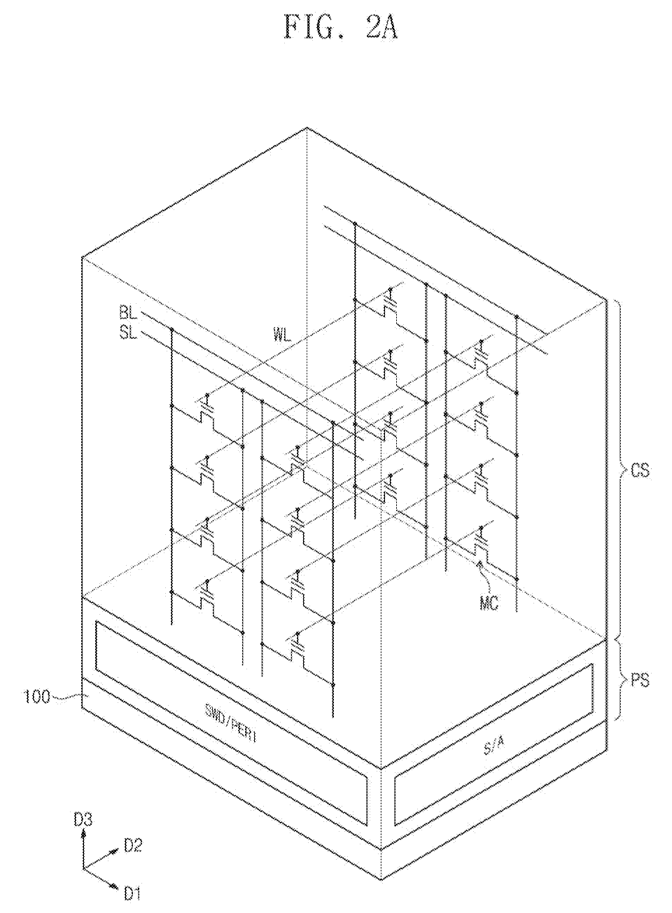

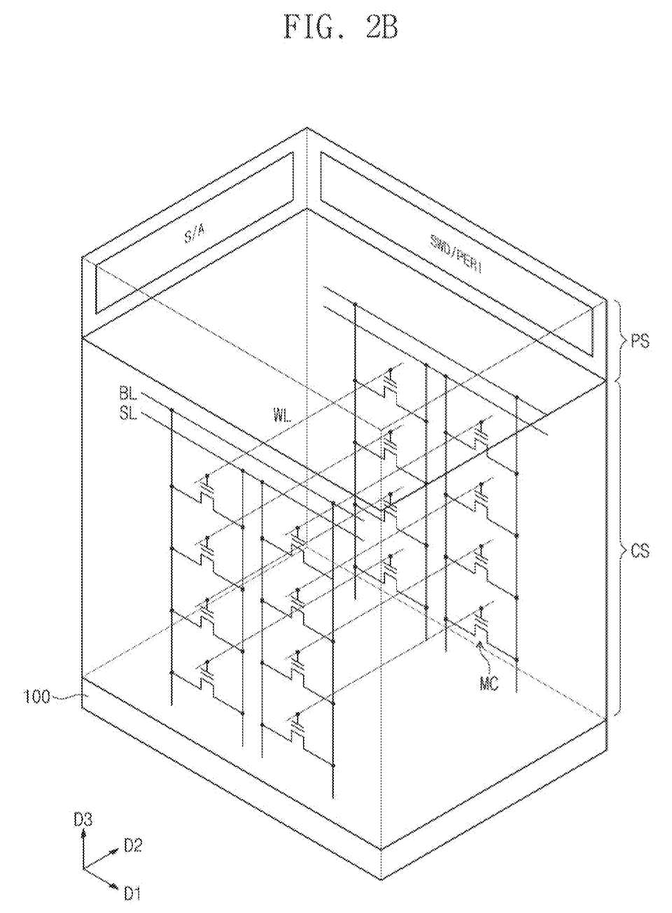

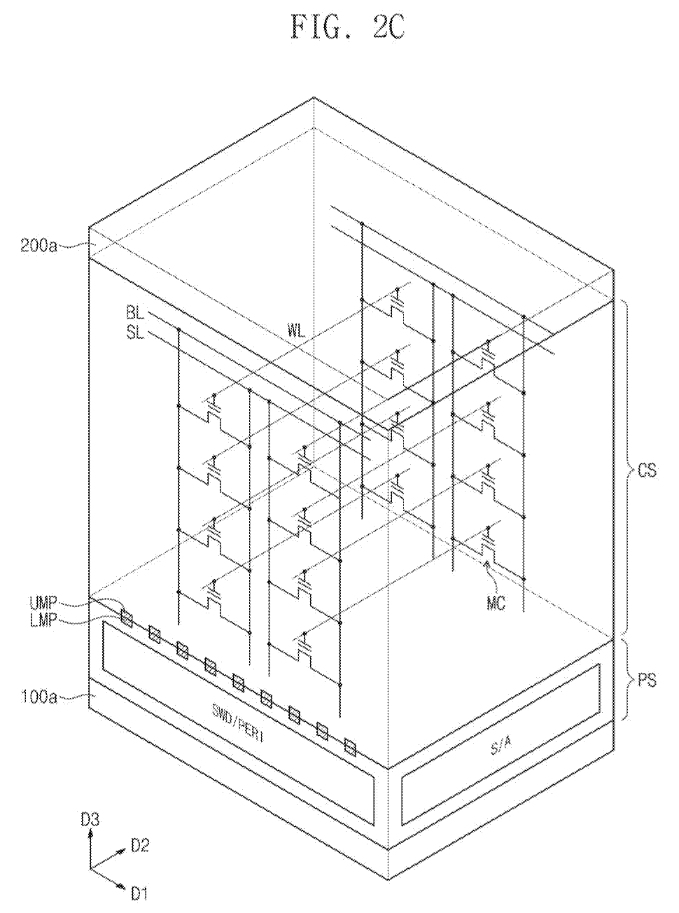

FIGS. 2A, 2B, and 2C are schematic perspective views illustrating a three-dimensional semiconductor device according to an embodiment of the present disclosure.

Referring to FIG. 2A, a three-dimensional semiconductor device may include a substrate 100, a peripheral circuit structure PS on the substrate 100, and a cell array structure CS on the peripheral circuit structure PS.

The peripheral circuit structure PS may include core and peripheral circuits formed on the substrate 100. The core and peripheral circuits may include the row and column decoders 2 and 4, the sense amplifier 3, and the control logic 5 described with reference to FIG. 1.

The substrate 100 may be a plate-shaped structure that is extended parallel to a plane defined by a first direction D1 and a second direction D2. The first direction D1 and the second direction D2 may be parallel to a bottom surface of the substrate 100 and may not be parallel to each other. As an example, the first and second directions D1 and D2 may be horizontal directions that are orthogonal to each other. The peripheral circuit structure PS and the cell array structure CS may be sequentially stacked on the substrate 100 in a third direction D3 perpendicular to the bottom surface of the substrate 100.

The cell array structure CS may include the bit lines BL, the source lines SL, and the word lines WL, and the memory cells MC therebetween. Each of the memory cells MC may be connected to one of the word lines WL, one of the bit lines BL, and one of the source lines SL.

Referring to FIG. 2B, the semiconductor device may include the cell array structure CS on the substrate 100 and the peripheral circuit structure PS on the cell array structure CS. The cell array structure CS may be disposed between the substrate 100 and the peripheral circuit structure PS. The peripheral circuit structure PS may include the core and peripheral circuits.

Referring to FIG. 2C, the semiconductor device may have a chip-to-chip (C2C) structure. The peripheral circuit structure PS may be provided on a first substrate 100a. Lower metal pads LMP may be provided in the uppermost portion of the peripheral circuit structure PS. The lower metal pads LMP may be electrically connected to the core and peripheral circuits. The lower metal pads LMP may be bonded to upper metal pads UMP of the cell array structure CS.

The cell array structure CS may be provided below a second substrate 200a. The upper metal pads UMP may be provided in the lowermost portion of the cell array structure CS. The upper metal pads UMP may be electrically connected to the bit lines BL, the source lines SL, and the word lines WL. The upper metal pads UMP may be electrically connected to the memory cells MC.

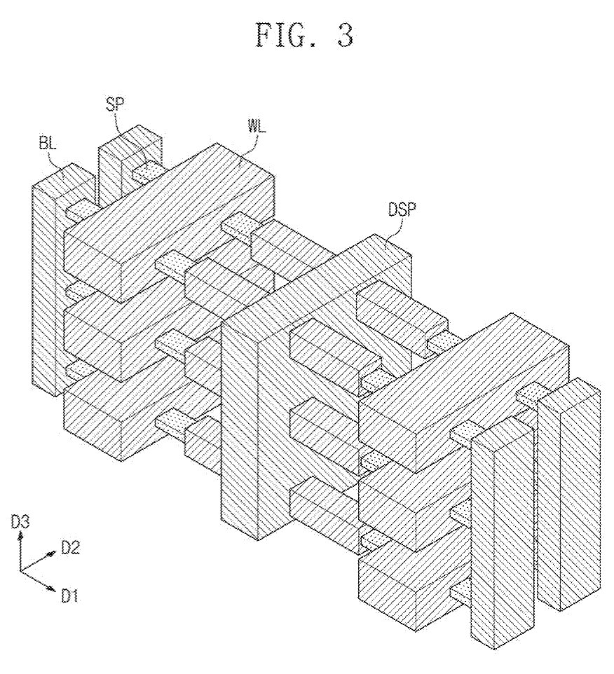

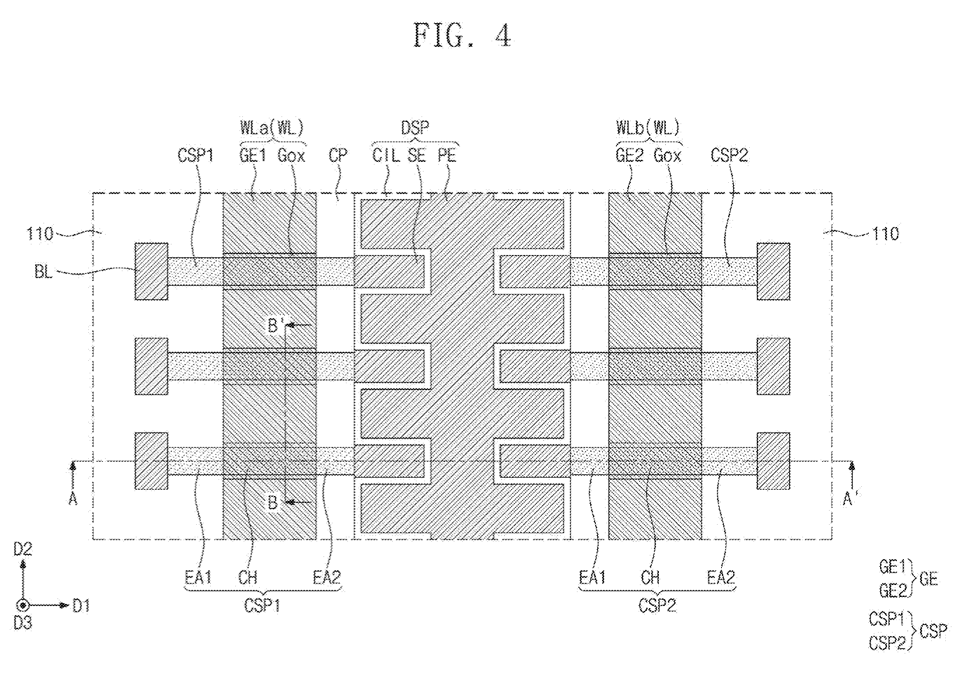

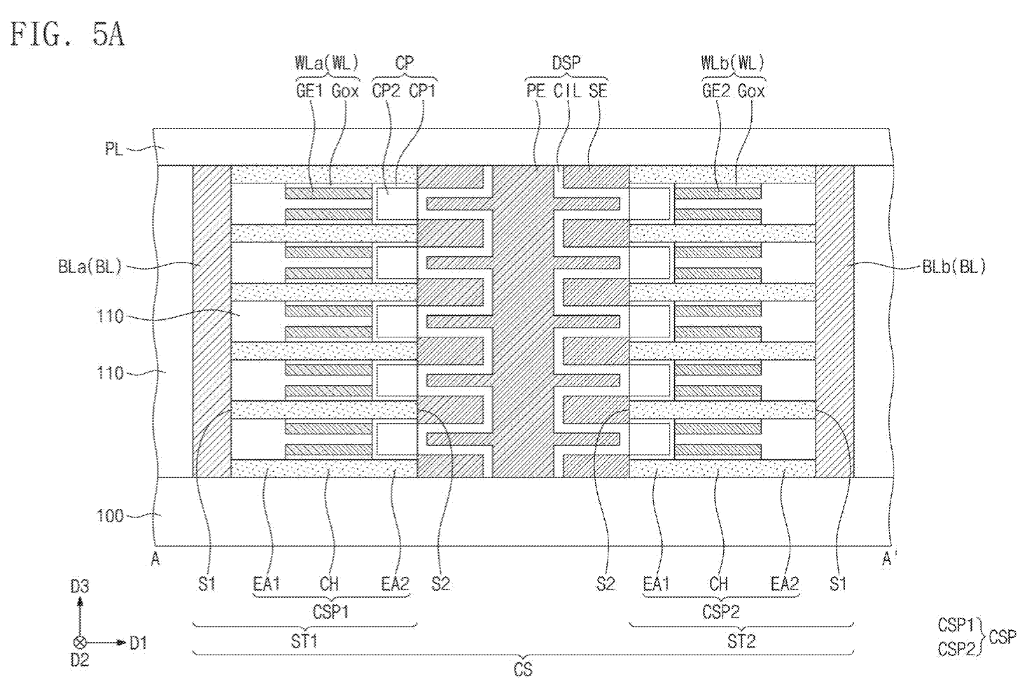

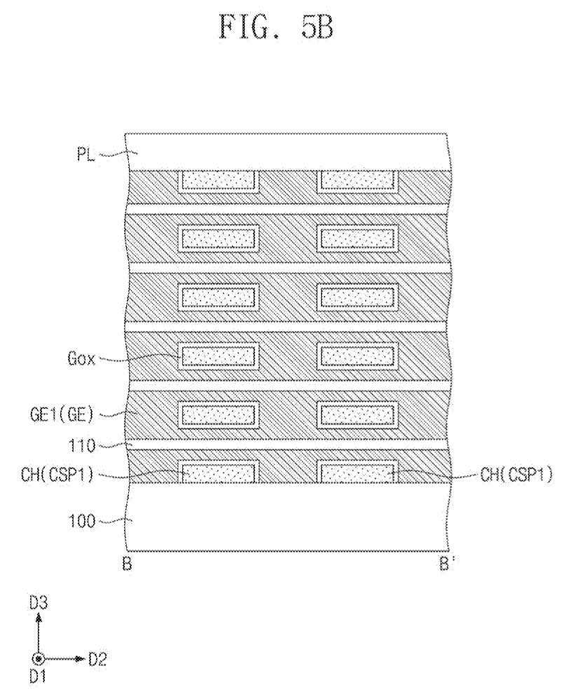

FIG. 3 is a perspective view illustrating semiconductor patterns, word lines, bit lines, and a data storage pattern, which are included in a three-dimensional semiconductor device according to an embodiment of the present disclosure. FIG. 4 is a plan view illustrating a three-dimensional semiconductor device according to an embodiment of the present disclosure. FIG. 5A is a cross-sectional view corresponding to a line A-A’ of FIG. 4. FIG. 5B is a cross-sectional view corresponding to a line B-B’ of FIG. 4.

Referring to FIGS. 3, 5A, and 5B, the three-dimensional semiconductor device may include the substrate 100. In an embodiment, the substrate 100 may be a semiconductor substrate, an insulating substrate, a silicon-on-insulator (SOI) substrate, or a germanium-on-insulator (GOI) substrate. The semiconductor substrate may be, for example, a silicon substrate, a germanium substrate, or a silicon-germanium substrate. The semiconductor substrate may be one of, for example, a single-crystalline semiconductor substrate, a polycrystalline semiconductor substrate, or an amorphous semiconductor substrate. The substrate 100 may be a plate-shaped structure that is extended parallel to a plane defined by the first and second directions D1 and D2.

The cell array structure CS may be provided on the substrate 100. The cell array structure CS may include a first stack ST1 and a second stack ST2, which are adjacent to each other in the first direction D1, and a data storage pattern DSP, which is provided therebetween. In an embodiment, the cell array structure CS may include a plurality of cell array structures CS, which are adjacent to each other in the first direction D1. Hereinafter, just one cell array structure CS will be described, for brevity’s sake, but other cell array structures CS may also have substantially the same features as described below.

Each of the first and second stacks ST1 and ST2 may include crystalline semiconductor patterns CSP, the word lines WL, the bit lines BL, first capping patterns CP1, second capping patterns CP2, and a gapfill insulating pattern 110. In an embodiment, the first and second stacks ST1 and ST2 may be provided to have a mirror symmetry with respect to the data storage pattern DSP.

The crystalline semiconductor pattern CSP may be provided on the substrate 100 and may be extended in the first direction D1. In an embodiment, the crystalline semiconductor pattern CSP may have a bar-shaped structure extending in the first direction D1. The crystalline semiconductor pattern CSP may include a first edge portion EA1 and a second edge portion EA2, which are spaced apart from each other in the first direction D1, and a channel region CH, which is provided therebetween. The channel region CH of the crystalline semiconductor pattern CSP may be at least partially surrounded by the word line WL. The first edge portion EA1 of the crystalline semiconductor pattern CSP may be in contact with the bit line BL. The first edge portion EA1 may be in contact with and electrically connected to the bit line BL. The second edge portion EA2 may be in contact with the data storage pattern DSP. The second edge portion EA2 may be in contact with and electrically connected to the data storage pattern DSP.

The crystalline semiconductor pattern CSP may have a first side surface S1 and a second side surface S2, which are opposite to each other. The first side surface S1 may be a side surface of the first edge portion EA1, and the second side surface S2 may be a side surface of the second edge portion EA2. The first side surface S1 of the crystalline semiconductor pattern CSP may be in contact with the bit line BL, and the second side surface S2 may be in contact with the data storage pattern DSP. The crystalline semiconductor pattern CSP may be formed of or include a single-crystalline semiconductor material. In an embodiment, the single-crystalline semiconductor material may be single-crystalline silicon.

In an embodiment, each of the first and second edge portions EA1 and EA2 of the crystalline semiconductor pattern CSP may include an impurity region that is doped with impurities (e.g., n- or p-type impurities). The impurity region may constitute a source drain region of a transistor.

In an embodiment, a plurality of crystalline semiconductor patterns CSP may be provided. The crystalline semiconductor patterns CSP may be adjacent to each other in the second and third directions D2 and D3. The crystalline semiconductor patterns CSP, which are adjacent to each other in the third direction D3, may be vertically overlapped with each other. The crystalline semiconductor patterns CSP, which are adjacent to each other in the third direction D3, may have side surfaces that are aligned to each other.

The crystalline semiconductor pattern CSP may include a first crystalline semiconductor pattern CSP1 provided in the first stack ST1 and a second crystalline semiconductor pattern CSP2 provided in the second stack ST2. The first crystalline semiconductor pattern CSP1 may be adjacent to the second crystalline semiconductor pattern CSP2 in the first direction D1. The first and second edge portions EA1 and EA2 of the first crystalline semiconductor pattern CSP1 may be sequentially arranged in the first direction D1. The first and second edge portions EA1 and EA2 of the second crystalline semiconductor pattern CSP2 may be sequentially arranged in the opposite direction of the first direction D1.

The word line WL may be provided to at least partially surround the channel region CH of the crystalline semiconductor pattern CSP and may be extended in the second direction D2. In an embodiment, the word line WL may have a structure (i.e., a gate-all-around structure) partially or fully surrounding the channel region CH of the crystalline semiconductor pattern CSP. Each word line WL may at least partially surround the channel region CH of each of the crystalline semiconductor patterns CSP, which are adjacent to each other in the second direction D2. In an embodiment, a plurality of word lines WL may be provided. Each of the word lines WL may be extended in the second direction D2 to at least partially surround the channel region CH of a corresponding one of the crystalline semiconductor patterns CSP, which are adjacent to each other in the third direction D3.

The first and second crystalline semiconductor patterns CSP1 and CSP2, which are adjacent to each other in the first direction D1, may include the same semiconductor material but may have different crystalline directions from each other. At least two patterns of the first crystalline semiconductor patterns CSP1, which are stacked in the first stack ST1, may have different crystalline directions from each other. At least two patterns of the second crystalline semiconductor patterns CSP2, which are stacked in the second stack ST2, may have different crystalline directions from each other. For example, the first crystalline semiconductor patterns CSP1, which are adjacent to each other in the third direction D3, and/or the second crystalline semiconductor patterns CSP2, which are adjacent to each other in the third direction D3, may have different crystalline directions from each other.

A first crystalline semiconductor pattern CPS1, which is the lowermost one of the first crystalline semiconductor patterns CSP1, and a second crystalline semiconductor pattern CSP2, which is the lowermost one of the second crystalline semiconductor patterns CPS2, may be in contact with a top surface of the substrate 100 or may be floated from the substrate 100. For example, the uppermost portion of the substrate 100 may include a semiconductor layer. In this case, the crystalline direction of the semiconductor layer of the substrate 100 may be different from the crystalline direction of the first crystalline semiconductor pattern CPS1. The crystalline direction of the semiconductor layer of the substrate 100 may be different from the crystalline direction of the second crystalline semiconductor pattern CPS2. As will be described above, the first and second crystalline semiconductor patterns CSP1 and CSP2 may be formed to have a single-crystalline structure by a metal-induced crystallization method performed in the first direction D1, not by an epitaxial growth method performed in the third direction D3 on the substrate 100. Thus, the first and second crystalline semiconductor patterns CSP1 and CSP2 may have a single crystalline structure, regardless of the material and crystalline direction of the substrate 100. The channel region CH of the crystalline semiconductor pattern CSP may not substantially contain metal. For example, the metal concentration in the channel region CH may be equal to or lower than 100 ppm.

The word line WL may include the first word line WLa, which is provided in the first stack ST1 to at least partially surround the channel region CH of the first crystalline semiconductor pattern CSP1, and the second word line WLb, which is provided in the second stack ST2 to at least partially surround the channel region CH of the second crystalline semiconductor pattern CSP2.

The word line WL may include a gate dielectric layer Gox, which is provided to at least partially surround the channel region CH of the crystalline semiconductor pattern CSP, and a gate electrode GE, which is provided on the gate dielectric layer Gox to at least partially surround the channel region CH of the crystalline semiconductor pattern CSP. The gate electrode GE may include a first gate electrode GE1, which is provided to at least partially surround the channel region CH of the first crystalline semiconductor pattern CSP1, and a second gate electrode GE2, which is provided to at least partially surround the channel region CH of the second crystalline semiconductor pattern CSP2. The gate electrode GE may be formed of or include at least one of, for example, doped polysilicon, metallic materials (e.g., Al, Cu, Ti, Ta, Ru, W, Mo, Pt, Ni, and Co), conductive metal nitride materials (e.g., TiN, TaN, WN, NbN, TiAlN, TiSiN, TaSiN, and RuTiN), conductive metal silicide materials, or conductive metal oxide materials (e.g., PtO, RuO₂, IrO₂, SRO (SrRuO₃), BSRO ((Ba,Sr)RuO₃), CRO (CaRuO₃), and LSCo), but the present disclosure is not limited to this example. The gate electrode GE may have a single-layered or multi-layered structure composed of at least one of the above materials. In an embodiment, the gate electrode GE may be formed of or include a two-dimensional semiconductor material (e.g., graphene, carbon nanotube, or combinations thereof).

In an embodiment, the gate dielectric layer Gox may be formed of or include at least one of high-k dielectric materials, silicon oxide, silicon nitride, or silicon oxynitride and may have a single- or multi- layered structure. In the present specification, the high-k dielectric material may be defined as a material having a dielectric constant higher than silicon oxide.

Referring back to FIGS. 3 to 5B, the bit line BL may be provided on the first side surface S1 of the crystalline semiconductor pattern CSP (i.e., the side surface of the first edge portion EA1). The bit line BL may be extended in the third direction D3, on the first side surface S1 of the crystalline semiconductor pattern CSP. Thus, the bit line BL may be in contact with and electrically connected to the first side surface S1 of each of the crystalline semiconductor patterns CSP, which are adjacent to each other in the third direction D3. In an embodiment, a plurality of bit lines BL may be provided. The bit lines BL may be adjacent to each other in the second direction D2.

The bit line BL may be a single layer, which is made of a single material, or a composite layer including two or more materials. The bit line BL may be formed of or include at least one of metallic materials (e.g., Ti, Mo, W, Cu, Al, Ta, Ru, Ir, and Co), metal nitride materials (e.g., containing Ti, Mo, W, Cu, Al, Ta, Ru, Ir, and Co), or metal silicide materials (e.g., containing Ti, Mo, W, Cu, Al, Ta, Ru, Ir, and Co).

The bit line BL in the first stack ST1 may include a first bit line BLa, which is provided on the first side surface S1 of the first crystalline semiconductor pattern CSP1, and a second bit line BLb, which is provided on the first side surface S1 of the second crystalline semiconductor pattern CSP2.

The data storage pattern DSP may be interposed between the first stack ST1 and the second stack ST2. The data storage pattern DSP may be interposed between the first and second crystalline semiconductor patterns CSP1 and CSP2. The data storage pattern DSP may be in contact with the second side surface S2 of the first crystalline semiconductor pattern CSP1 (i.e., the side surface of the second edge portion EA2) and may be electrically connected to the first crystalline semiconductor pattern CSP1. The data storage pattern DSP may be in contact with the second side surface S2 of the second crystalline semiconductor pattern CSP2 and may be electrically connected to the second crystalline semiconductor pattern CSP2.

The data storage pattern DSP may include a storage electrode SE, a plate electrode PE, and a capacitor dielectric layer CIL therebetween. In an embodiment, the three-dimensional semiconductor device may be a dynamic random access memory (DRAM) device, and here, the data storage pattern DSP may be used as a capacitor. The storage electrode SE may be spaced apart from the plate electrode PE by the capacitor dielectric layer CIL.

Each of the storage and plate electrodes SE and PE may include a conductive material. In an embodiment, each of the storage and plate electrodes SE and PE may be formed of or include at least one of doped silicon (Si), doped silicon germanium (SiGe), metallic materials (e.g., Ti, Mo, W, Cu, Al, Ta, Ru, Ir, Co, Pt, Au, and Ag), metal nitride materials (e.g., nitride materials containing Ti, Mo, W, Cu, Al, Ta, Ru, Ir, Co, Pt, Au, and Ag), titanium silicon nitride (e.g., TiSiN), titanium aluminum nitride (e.g., TiAlN), tantalum aluminum nitride (e.g., TaAlN), conductive oxide materials (e.g., PtO, RuO₂, IrO₂, SrRuO₃ (SRO), (Ba,Sr)RuO₃ (BSRO), CaRuO₃ (CRO), and LSCo), or metal silicide materials. Each of the storage and plate electrodes SE and PE may be a single layer, which is made of a single material, or a composite layer including two or more materials.

In an embodiment, the capacitor dielectric layer CIL may include at least one of metal oxide materials (e.g., HfO₂, ZrO₂, Al₂O₃, La₂O₃, Ta₂O₃, and TiO₂) and perovskite dielectric materials (e.g., SrTiO₃ (STO), (Ba,Sr)TiO₃ (BST), BaTiO₃, PZT, and PLZT).

In another embodiment, the data storage pattern DSP may be a variable resistance pattern whose resistance can be switched to one of at least two states by an electric pulse applied thereto. For example, the data storage pattern DSP may be formed of or include at least one of phase-change materials whose crystal state can be changed depending on an amount of a current applied thereto, perovskite compounds, transition metal oxide materials, magnetic materials, ferromagnetic materials, or antiferromagnetic materials.

The storage electrode SE may be provided on and extended from the second side surface S2 of the first crystalline semiconductor pattern CSP1 in the first direction D1. The storage electrode SE may be provided on and extended from the second side surface S2 of the second crystalline semiconductor pattern CSP2 in the opposite direction of the first direction D1. A silicide pattern may be provided between the storage electrode SE and the first crystalline semiconductor pattern CSP1 and between the storage electrode SE and the second crystalline semiconductor pattern CSP2. The silicide pattern may be formed of or include at least one of metal silicide materials (e.g., containing Ti, Mo, W, Cu, Al, Ta, Ru, Ir, and Co). In an embodiment, a plurality of storage electrodes SE may be provided to be adjacent to each other in the third direction D3.

The plate electrode PE may include a vertical portion extending in the third direction D3 and horizontal portions protruding from the vertical portion in the first direction D1 or an opposite direction of the first direction D1. The horizontal regions of the plate electrode PE may be interposed between the storage electrodes SE, which are adjacent to each other in the third direction D3.

The gapfill insulating pattern 110 may be provided on the substrate 100. The gapfill insulating pattern 110 may cover a side surface of the cell array structure CS. The gapfill insulating pattern 110 may be interposed between the bit line BL and the word line WL, between the crystalline semiconductor patterns CSP adjacent to each other in the third direction D3, between the first edge portions EA1 of the crystalline semiconductor patterns CSP adjacent to each other in the second direction D2, and between the word lines WL adjacent to each other in the third direction D3. The gapfill insulating pattern 110 may include a single or composite layer including an insulating material.

A capping pattern CP may be provided in the cell array structure CS. The capping pattern CP may be interposed between the word lines WL and the data storage pattern DSP. The capping pattern CP may be interposed between the crystalline semiconductor patterns CSP, which are adjacent to each other in the third direction D3. The capping pattern CP may be interposed between the second edge portions EA2 of the crystalline semiconductor patterns CSP, which are adjacent to each other in the second direction D2.

The capping pattern CP may include the first capping pattern CP1 surrounding the second edge portion EA2 of the crystalline semiconductor pattern CSP and the second capping pattern CP2 on the first capping pattern CP1. The first capping pattern CP1 may conformally cover the second edge portion EA2 of the crystalline semiconductor pattern CSP and the side surface of the word line WL. Each of the first and second capping patterns CP1 and CP2 may include an insulating material. The second capping pattern CP2 may include a single layer or a composite layer.

A protection layer PL may be provided on the cell array structure CS. The protection layer PL may cover top surfaces of the first stack ST1, the second stack ST2, and the data storage pattern DSP. The protection layer PL may include a single or composite layer including an insulating material. A plurality of upper interconnection lines may be provided in the protection layer PL. The upper interconnection lines may be electrically connected to the bit line BL and the data storage pattern DSP, respectively. In addition, word line pads may be provided on the side surface of the cell array structure CS and may be electrically connected to the word lines WL.

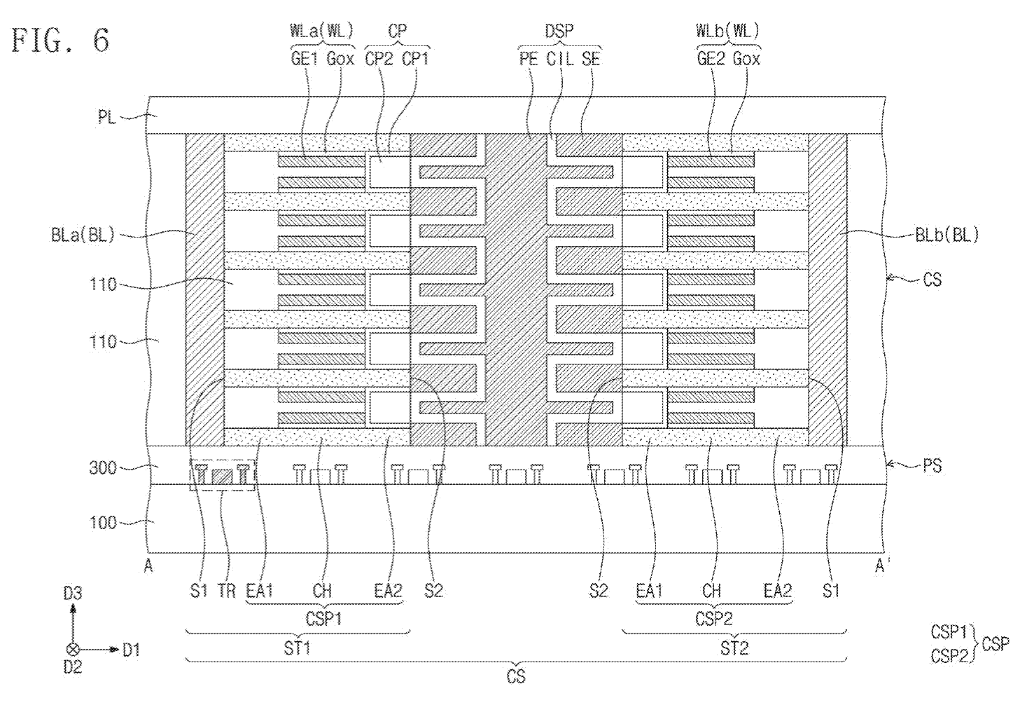

FIG. 6 is a cross-sectional view illustrating a three-dimensional semiconductor device according to an embodiment of the present disclosure. For concise description, an element previously described with reference to FIGS. 4 to 5B may be identified by the same reference number without repeating an overlapping description thereof.

Referring to FIGS. 6 and 2A, the peripheral circuit structure PS may be interposed between the substrate 100 and the cell array structure CS. The peripheral circuit structure PS may include a semiconductor substrate including at least one transistor TR and an insulating structure 300 covering the at least one transistor TR. In an embodiment, the crystalline semiconductor patterns CSP may be formed on the insulating structure 300. The crystalline semiconductor patterns CSP may be in contact with a top surface of the insulating structure 300.

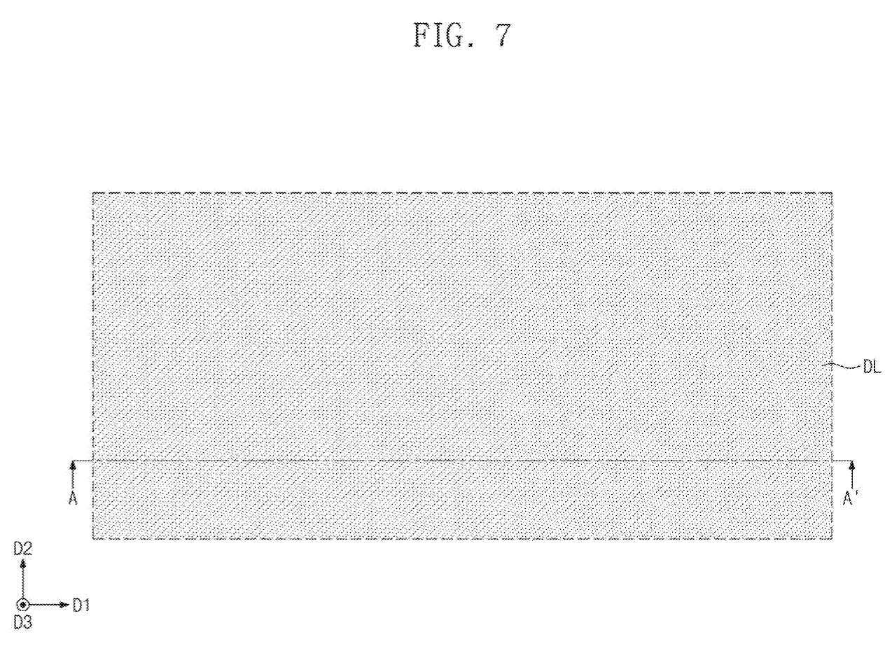

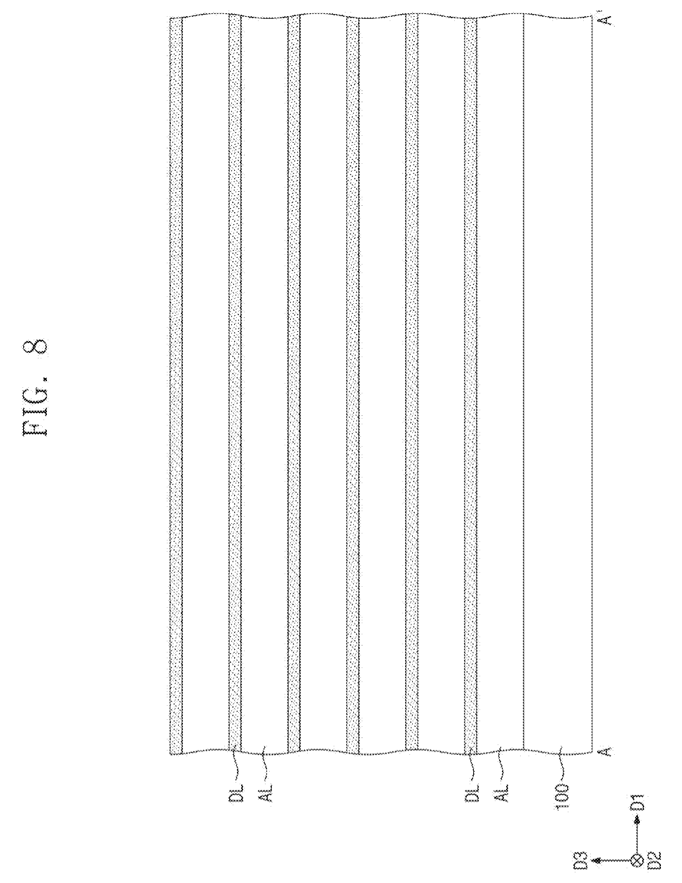

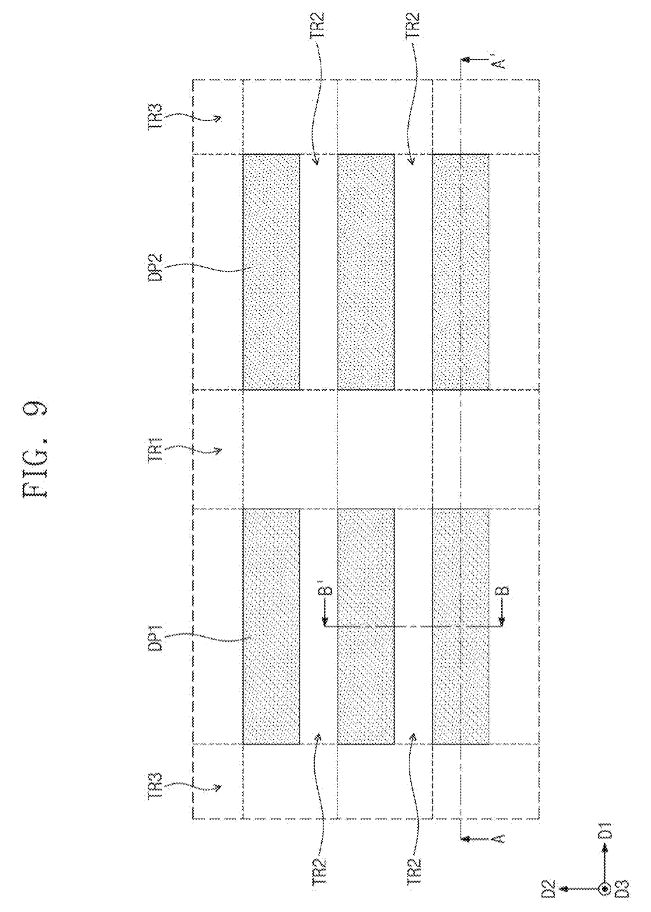

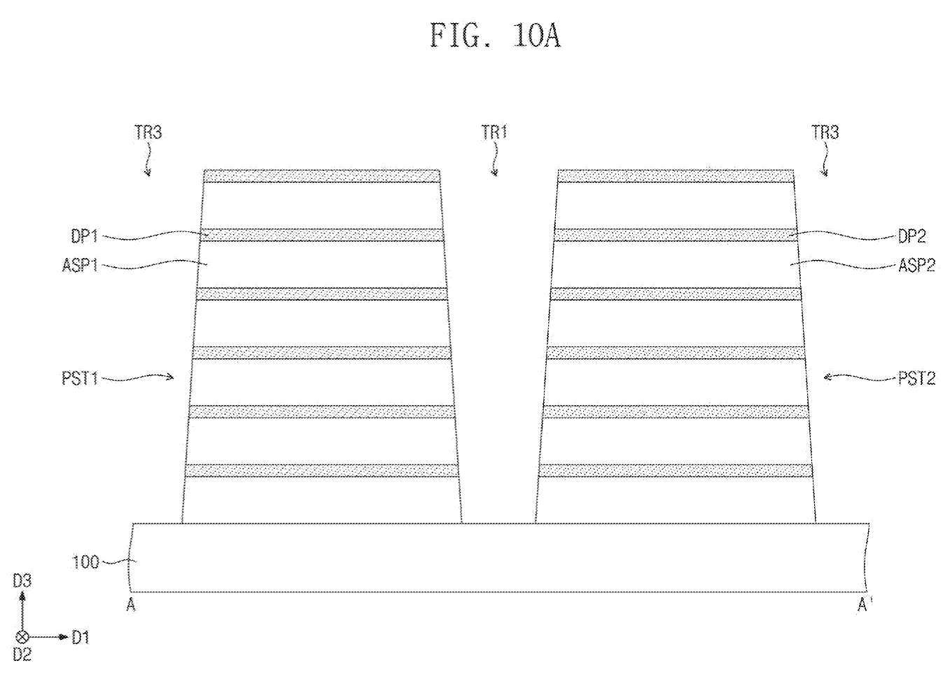

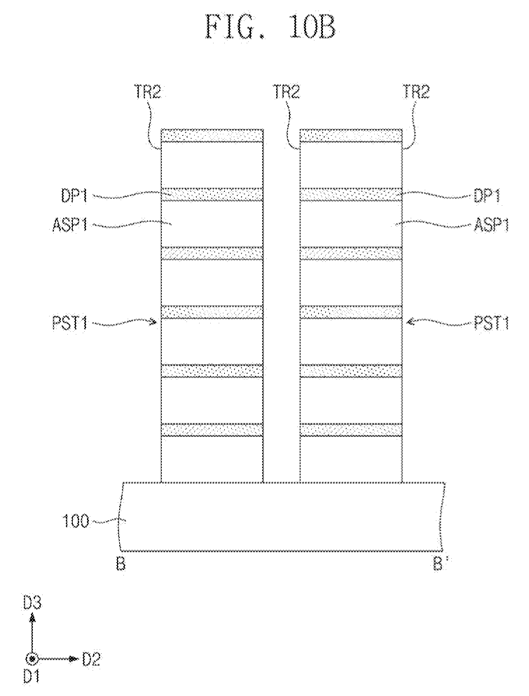

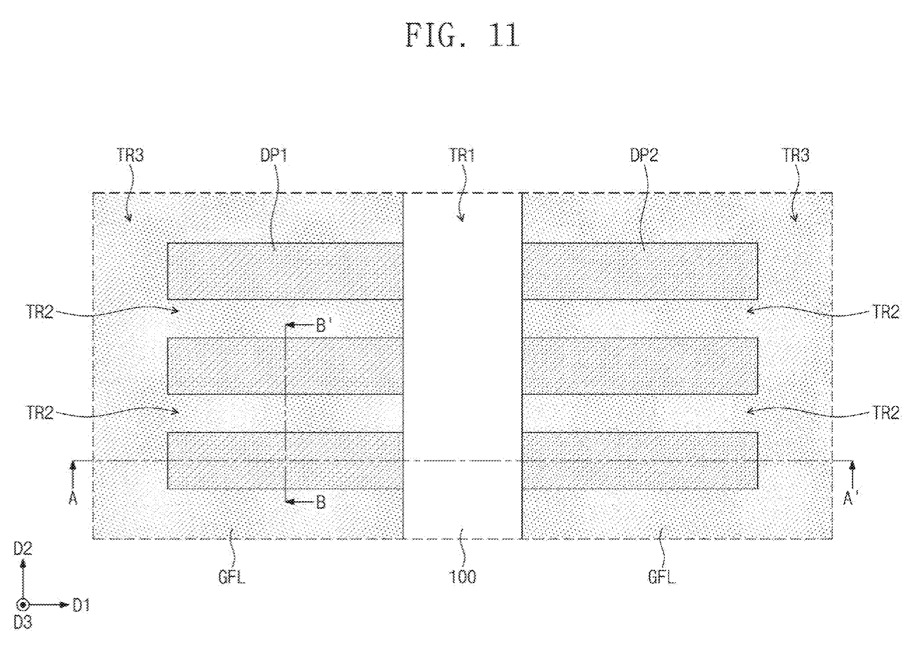

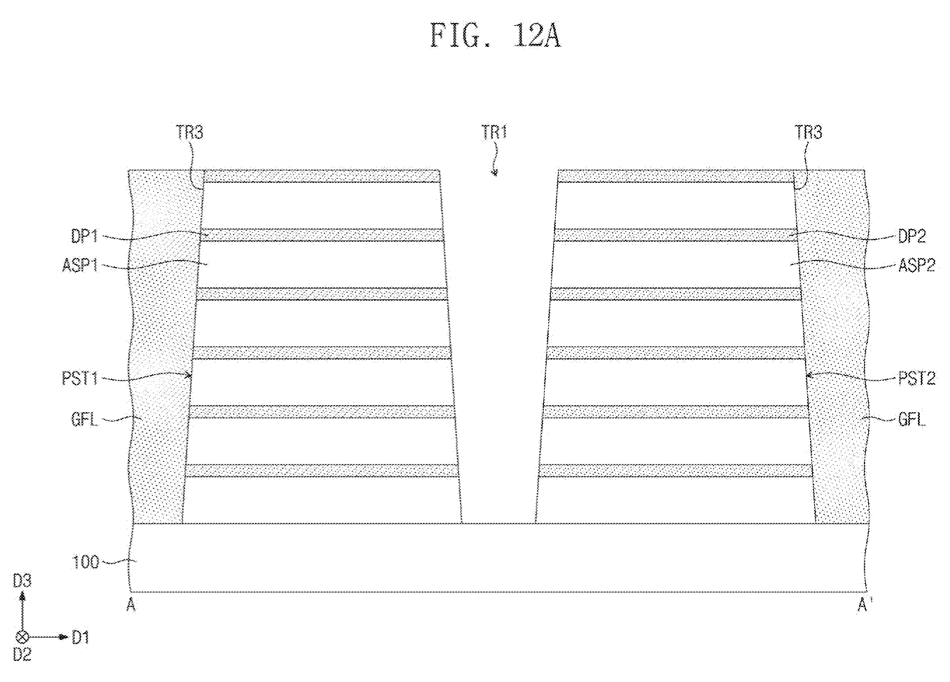

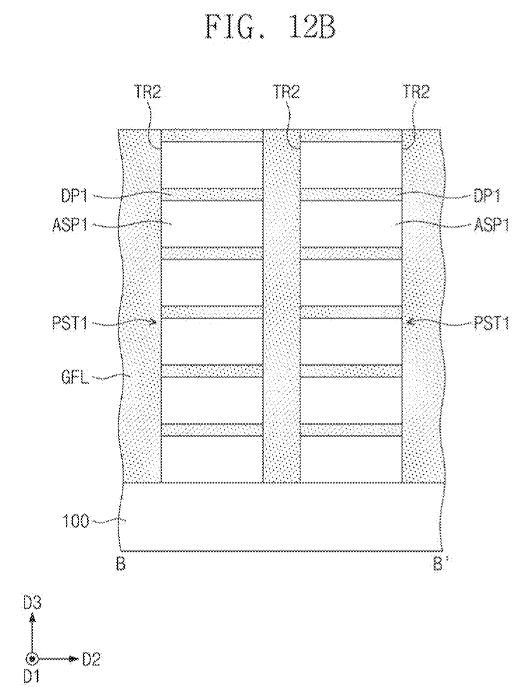

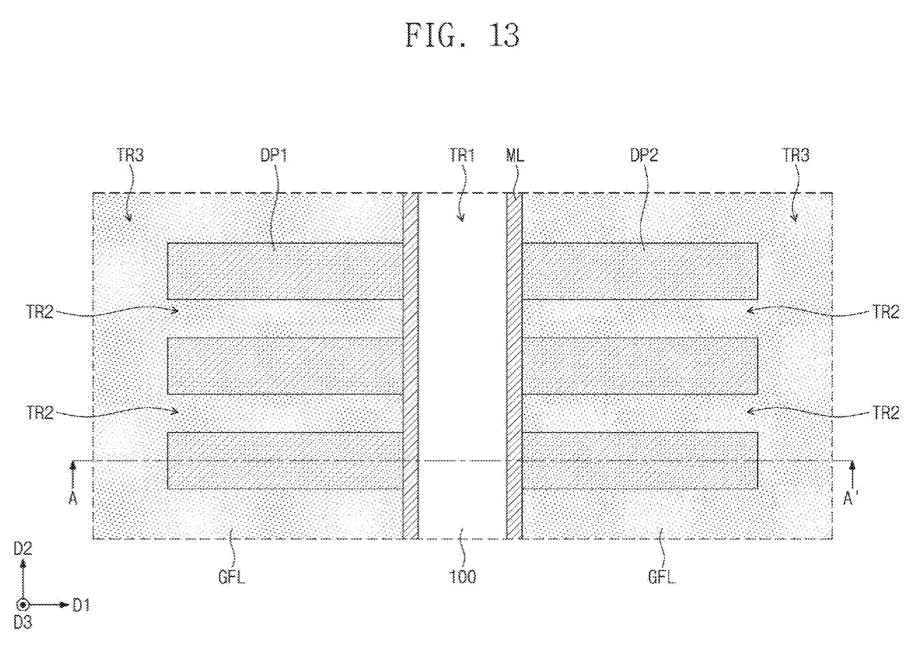

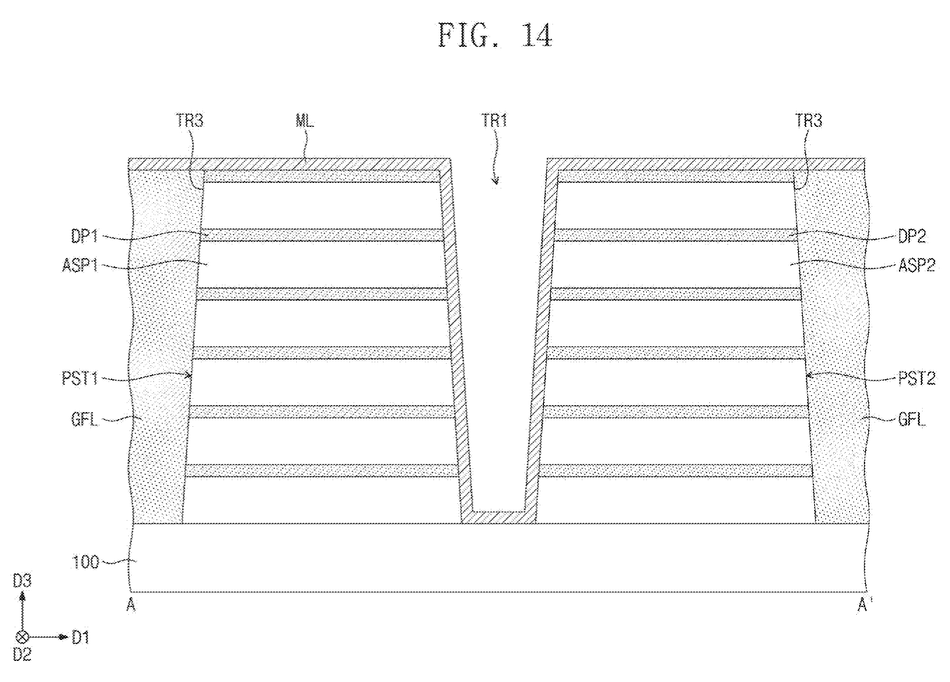

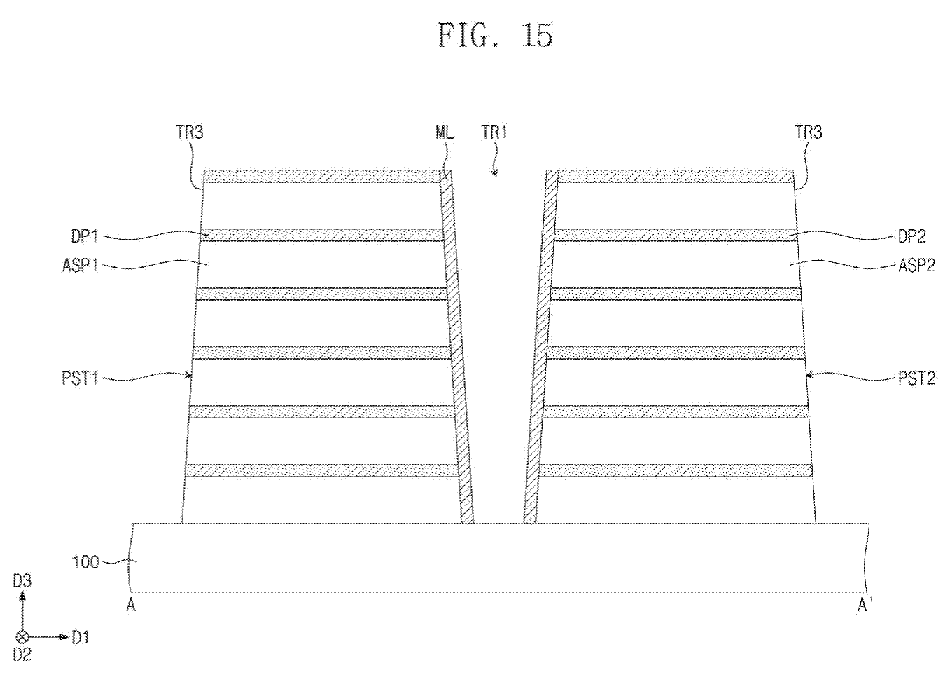

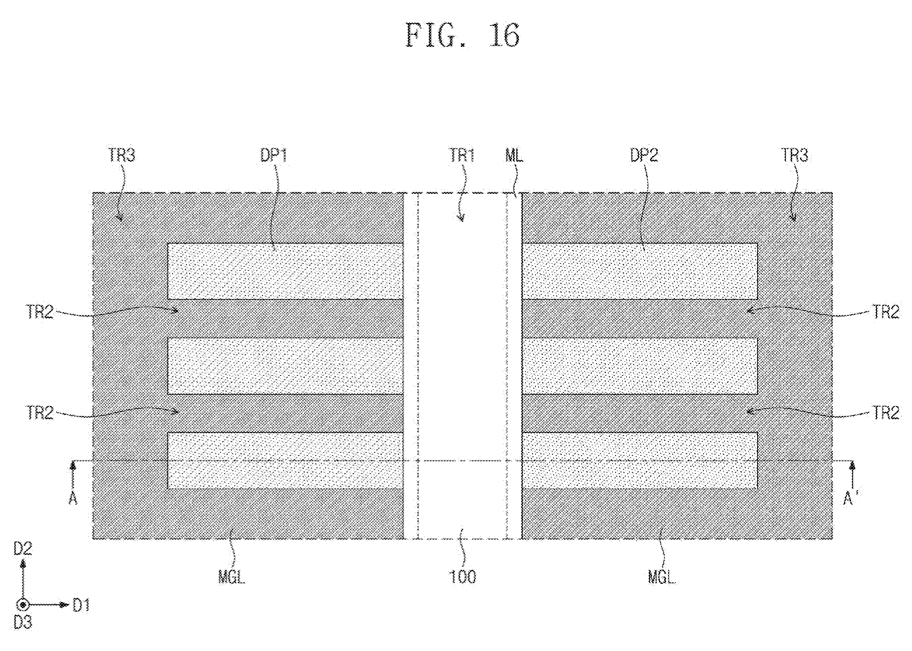

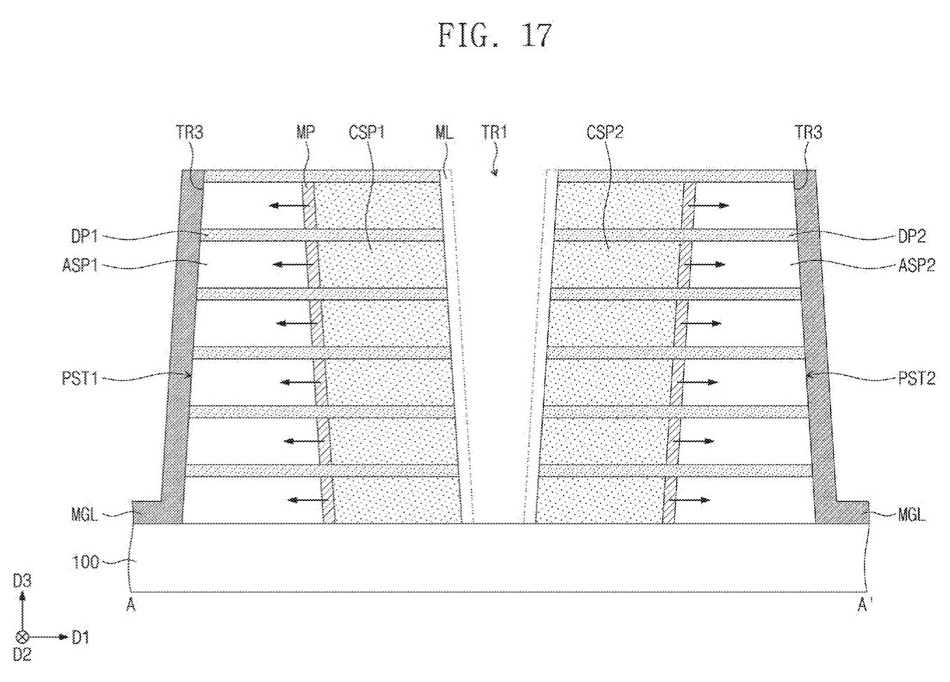

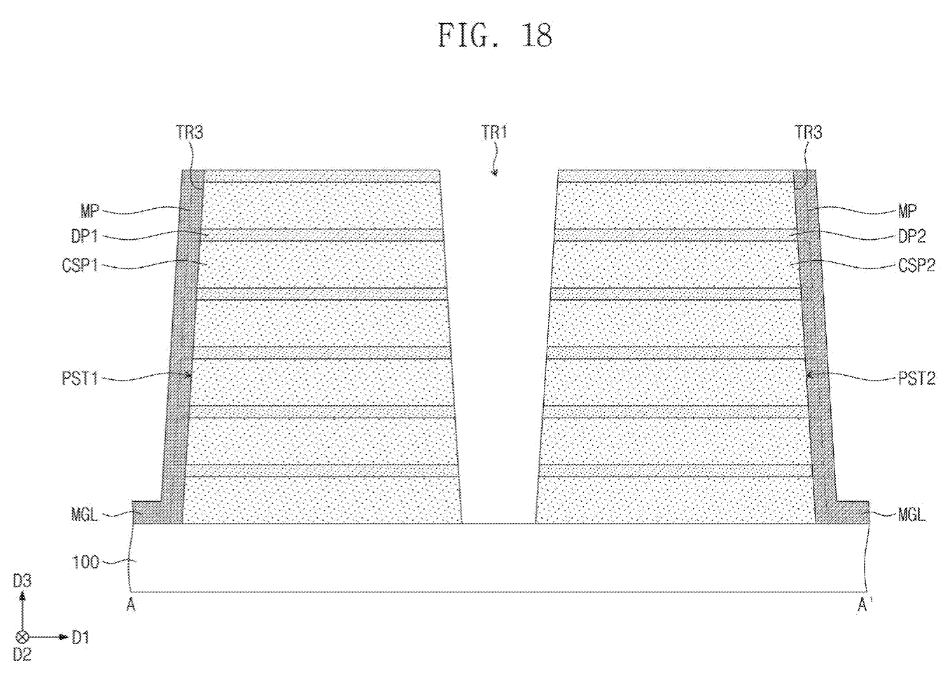

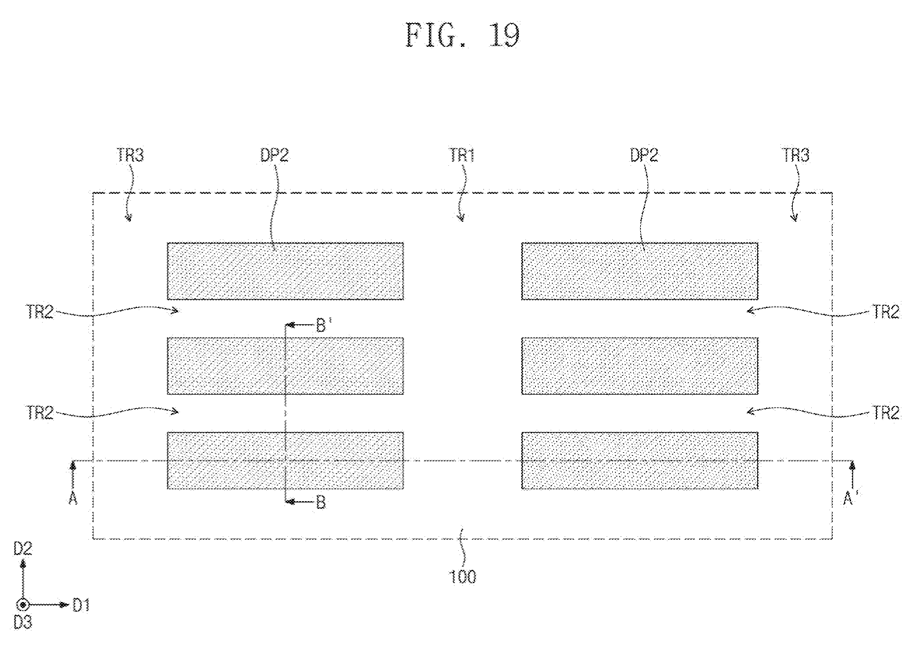

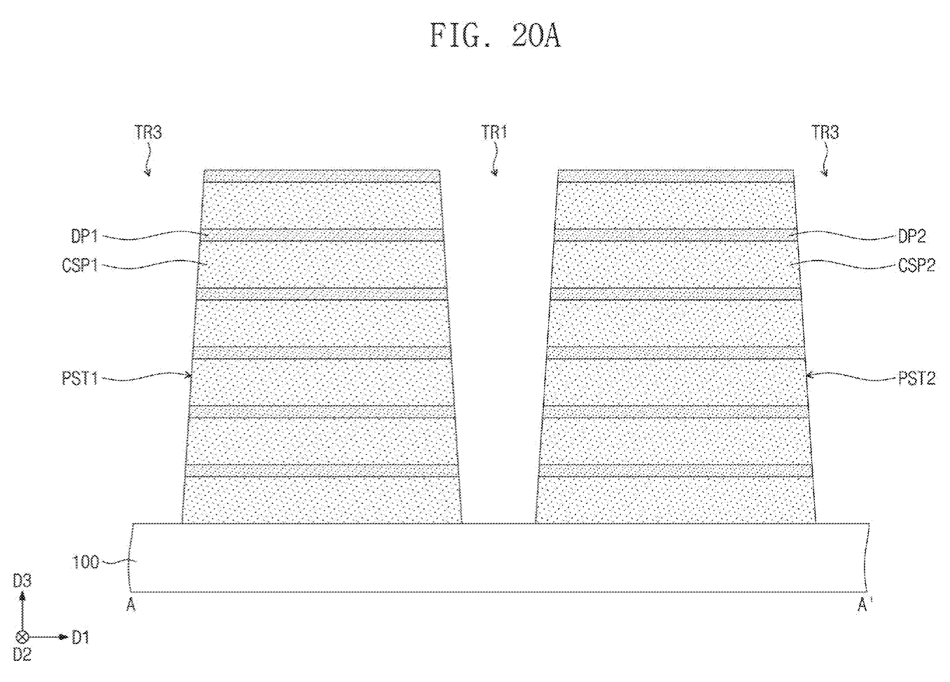

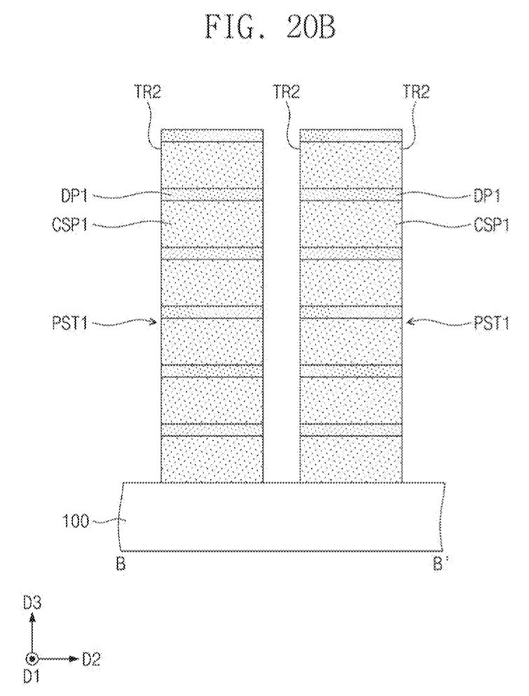

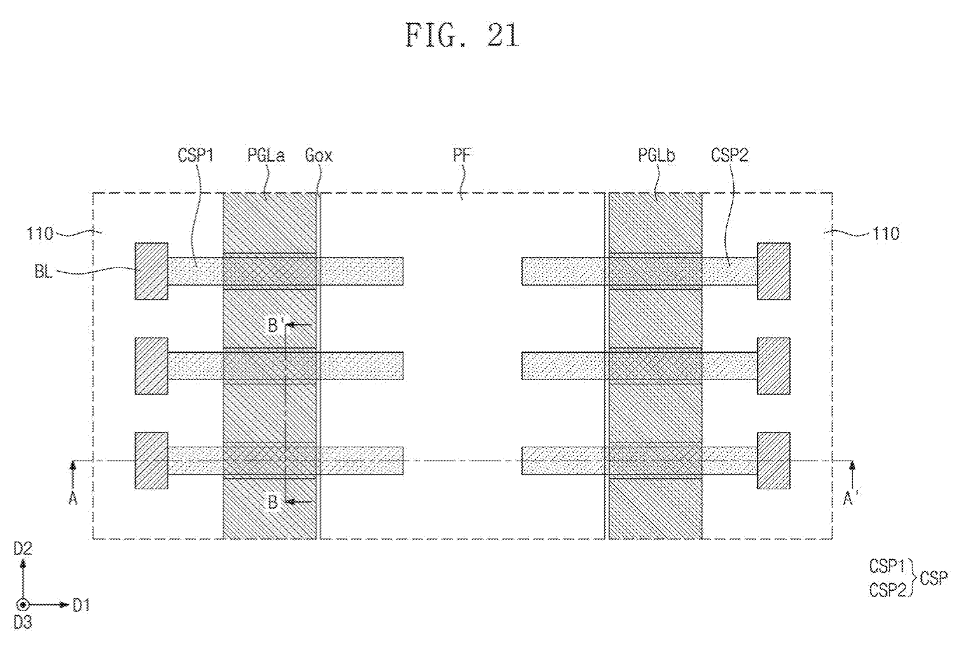

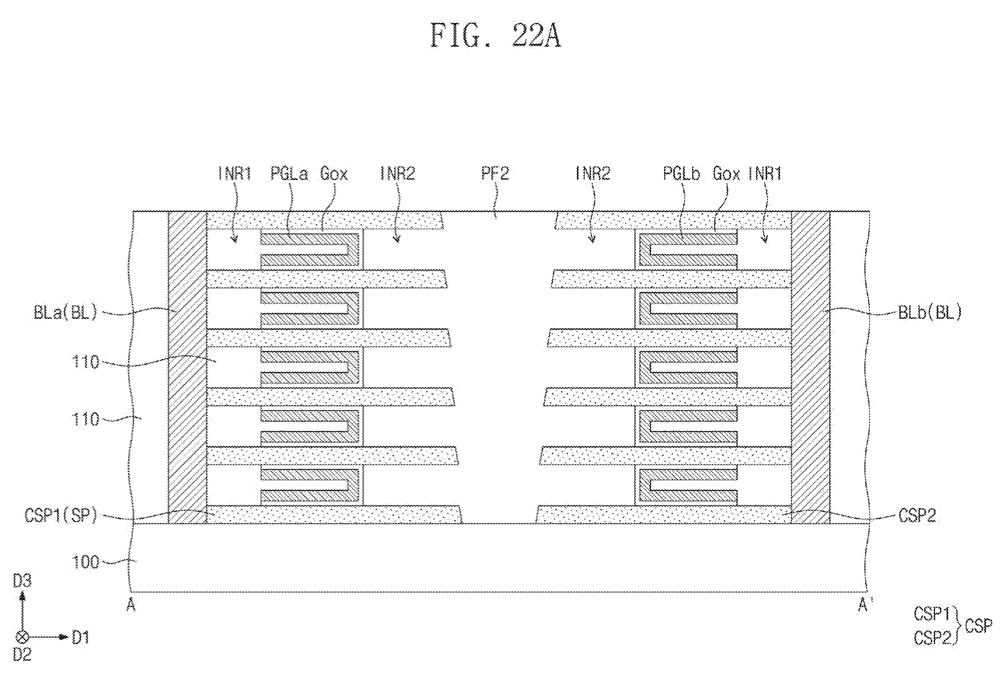

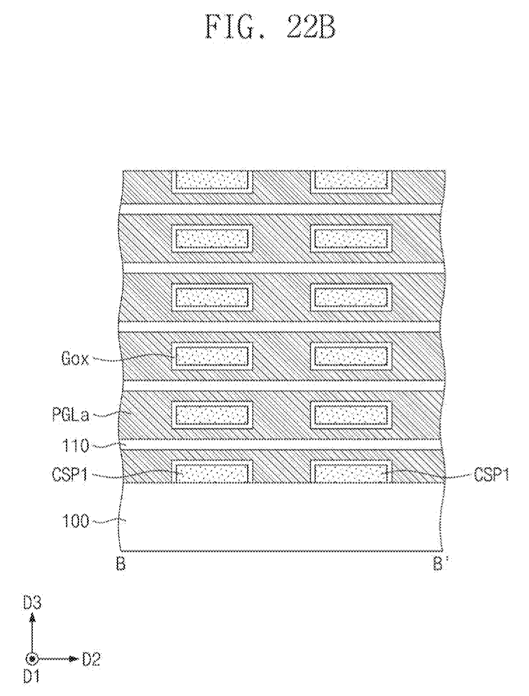

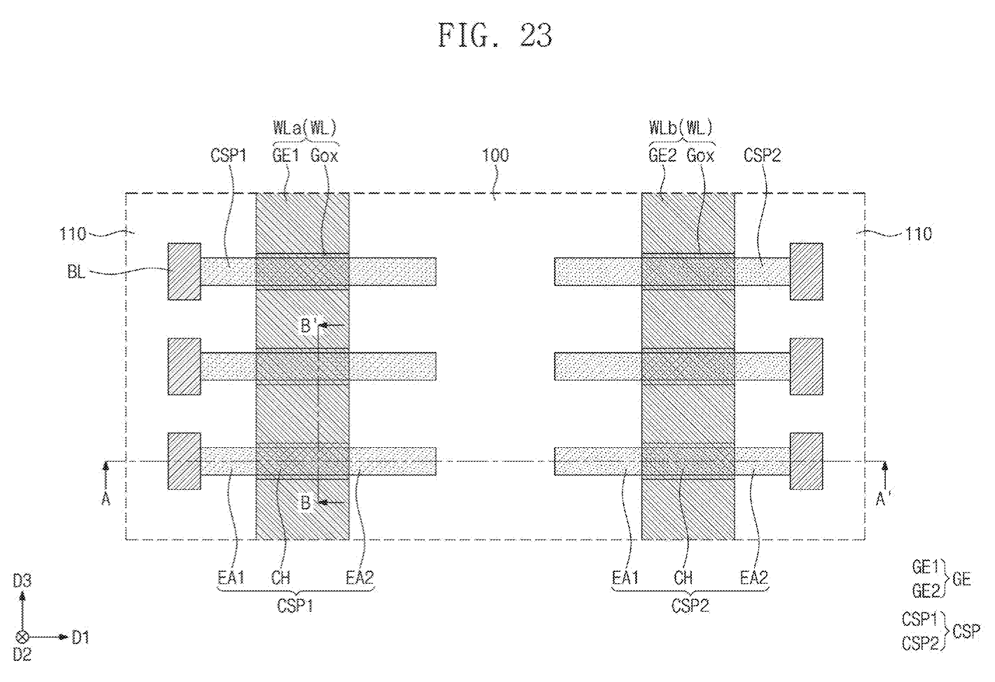

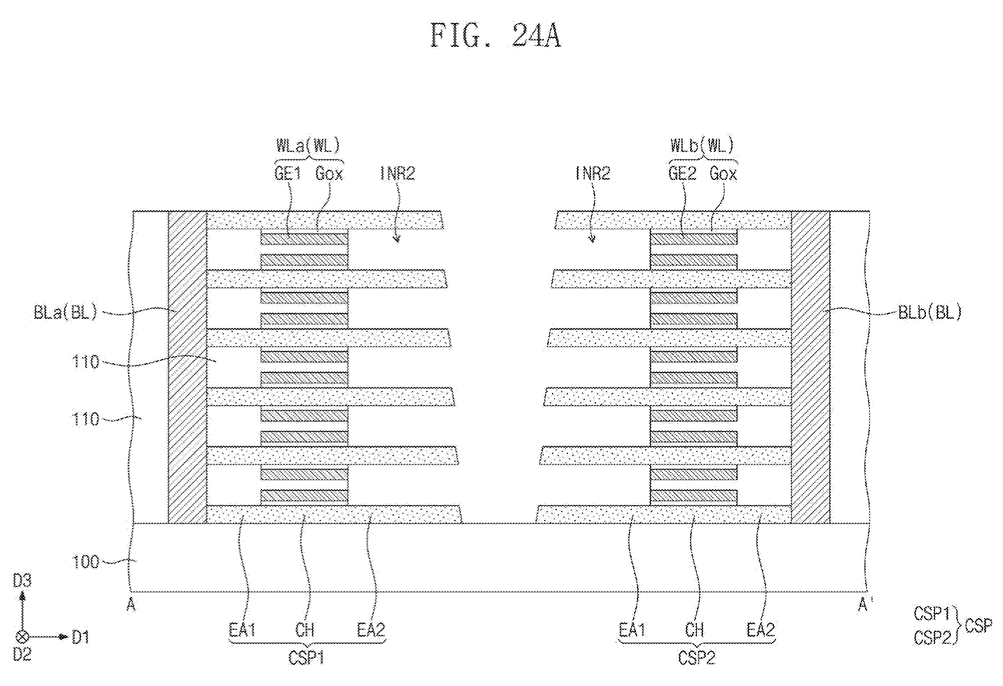

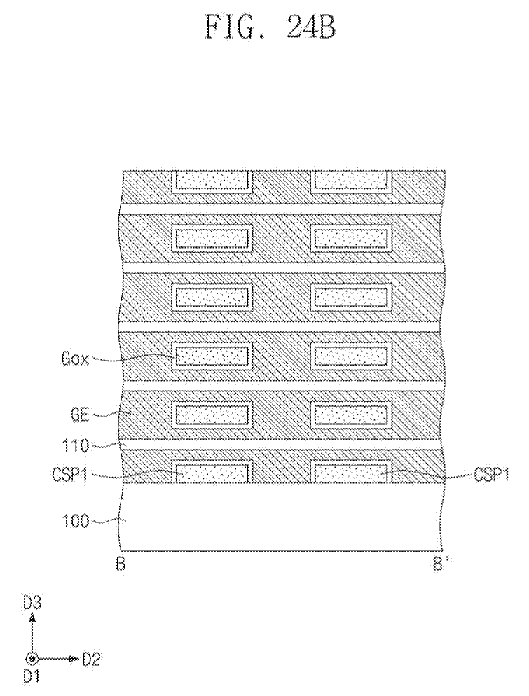

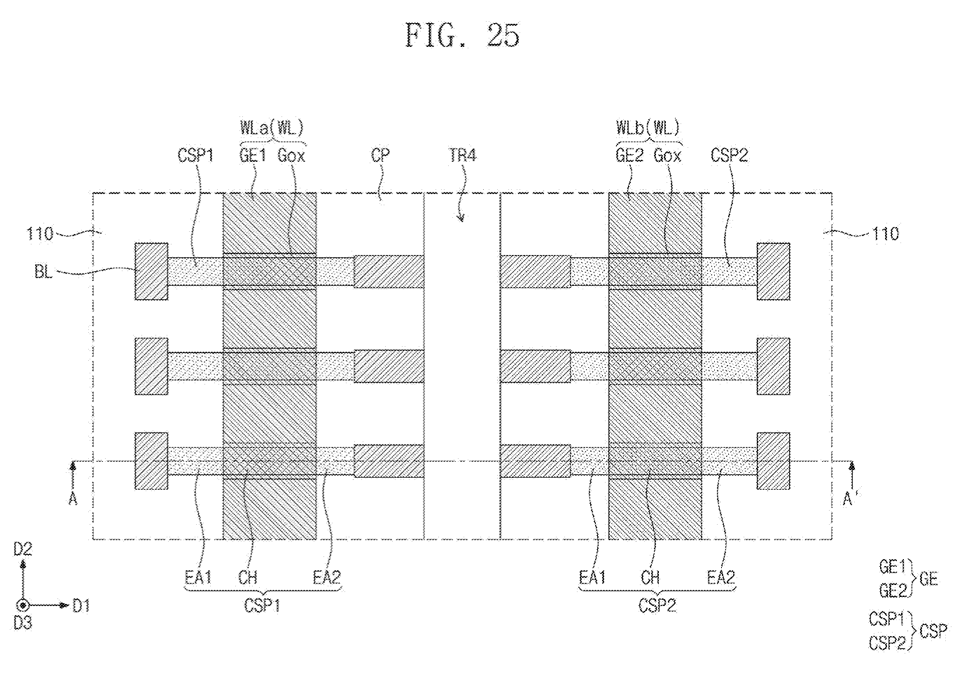

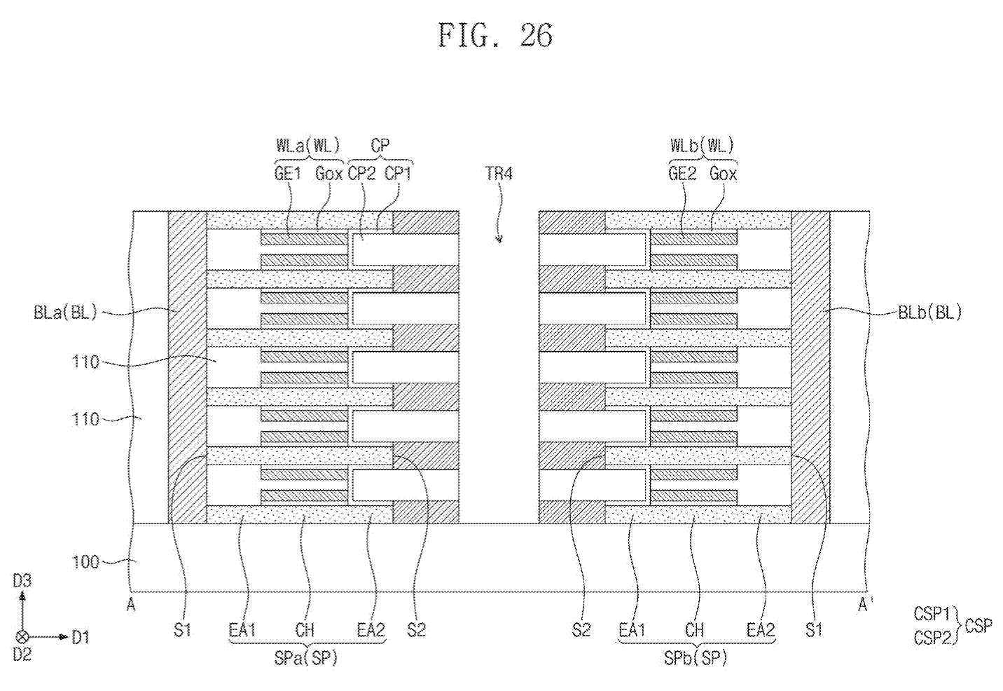

FIGS. 7 to 26 are diagrams illustrating a method of fabricating a three-dimensional semiconductor device, according to an embodiment of the present disclosure. In detail, FIGS. 7, 9, 11, 13, 16, 19, 21, 23, and 25 are plan views illustrating a method of fabricating a three- dimensional semiconductor device according to an embodiment of the present disclosure. FIG. 8 is a cross-sectional view illustrating a line A-A’ of FIG. 7. FIGS. 10A and 10B are cross-sectional views illustrating lines A-A’ and B-B’ of FIG. 9. FIGS. 12A and 12B are cross-sectional views illustrating lines A-A’ and B-B’ of FIG. 11. FIGS. 14 and 15 are cross-sectional views illustrating a line A-A’ of FIG. 13. FIGS. 17 and 18 are cross-sectional views illustrating a line A-A’ of FIG. 16. FIGS. 20A and 20B are cross-sectional views illustrating lines A-A’ and B-B’ of FIG. 19. FIGS. 22A and 22B are cross-sectional views illustrating lines A-A’ and B-B’ of FIG. 21. FIGS. 24A and 24B are cross-sectional views illustrating lines A-A’ and B-B’ of FIG. 23. FIG. 26 is a cross-sectional view illustrating a line A-A’ of FIG. 25.

Referring to FIGS. 7 and 8, the substrate 100 may be prepared. An amorphous semiconductor layer AL and insulating layers DL may be formed on the substrate 100 in an alternately stacked manner. The amorphous semiconductor layer AL may be formed of or include an amorphous semiconductor material. The amorphous semiconductor material may be one of, for example, silicon (Si), germanium (Ge), or silicon-germanium (SiGe). The amorphous semiconductor material may be, for example, silicon. The insulating layer DL may include an insulating material. The insulating material may be, for example, silicon oxide or silicon nitride. When measured in the third direction D3, the thickness of the amorphous semiconductor layer AL may be larger than the thickness of the insulating layer DL. The formation of the amorphous semiconductor layer AL and the insulating layer DL may include, for example, a deposition process. The deposition process may be, for example, a chemical vapor deposition process.

Referring to FIGS. 9, 10A, and 10B, a first trench TR1, second trenches TR2, and third trenches TR3 may be formed on the substrate 100 by removing a portion of each of the insulating layers DL and the amorphous semiconductor layers AL. The top surface of the substrate 100 may be partially exposed to the outside through the first, second, and third trenches TR1, TR2, and TR3. The first and third trenches TR1 and TR3 may be extended in the second direction D2. The second trench TR2 may be extended in the first direction D1. First preliminary stacks PST1 and second preliminary stacks PST2 may be formed through the removal process. The first trench TR1, the second trench TR2, and the third trench TR3 may be formed to cut the insulating layers DL and the amorphous semiconductor layers AL. The insulating layers DL may be cut to form a plurality of first insulating patterns DP1 and a plurality of second insulating patterns DP2. The amorphous semiconductor layers AL may be cut to form a plurality of first amorphous semiconductor patterns ASP1 and a plurality of second amorphous semiconductor patterns ASP2.

Each of the first preliminary stacks PST1 may include the first insulating patterns DP1 and the first amorphous semiconductor patterns ASP1. Each of the second preliminary stacks PST2 may include the second insulating patterns DP2 and the second amorphous semiconductor patterns ASP2. The first and second preliminary stacks PST1 and PST2 may be spaced apart from each other in the first direction D1, with the first trench TR1 interposed therebetween. Adjacent ones of the first preliminary stacks PST1 may be spaced apart from each other in the second direction D2, with the second trench TR2 interposed therebetween. Adjacent ones of the second preliminary stacks PST2 may be spaced apart from each other in the second direction D2, with the second trench TR2 interposed therebetween. The third trenches TR3 may be spaced apart from each other in the first direction D1, with the first trench TR1 interposed therebetween.

Each of the first and second insulating patterns DP1 and DP2 and the first and second amorphous semiconductor patterns ASP1 and ASP2 may have side surfaces which are opposite to each other in the first direction D1 and are exposed to the outside through the first and third trenches TR1 and TR3. Each of the first and second insulating patterns DP1 and DP2 and the first and second amorphous semiconductor patterns ASP1 and ASP2 may have side surfaces which are opposite to each other in the second direction D2 and are exposed to the outside through the second trench TR2.

Referring to FIGS. 11, 12A, and 12B, a sacrificial layer GFL may be formed to fill the second and third trenches TR2 and TR3. The sacrificial layer GFL may not fill the first trench TR1. For example, the sacrificial layer GFL may not cover side surfaces of the first insulating patterns DP1, side surfaces of the first amorphous semiconductor patterns ASP1, side surfaces of the second insulating patterns DP2, and side surfaces of the second amorphous semiconductor patterns ASP2, which are exposed through the first trench TR1. The sacrificial layer GFL may include a material having an etch selectivity with respect to the first and second insulating patterns DP1 and DP2. For example, the sacrificial layer GFL may be formed of or include one of silicon oxide (SiO), silicon nitride (SiN), silicon oxynitride (SiON), carbon (C), tungsten (W), and titanium nitride (TiN).

Referring to FIGS. 13 and 14, a metal layer ML may be formed to cover the side surface of each of the first and second preliminary stacks PST1 and PST2, which are exposed by the first trench TR1. The metal layer ML may cover the top surface of the substrate 100 exposed by the first trench TR1, the top surface of the sacrificial layer GFL, the top surface of each of the first preliminary stacks PST1, and the top surface of each of the second preliminary stacks PST2. In the case where the metal layer ML is in contact with the top surfaces of the first and second preliminary stacks PST1 and PST2, the metal layer ML may be in contact with the top surface of the first insulating pattern DP1, which is provided as the uppermost portion of the first preliminary stack PST1, and the top surface of the second insulating pattern DP2, which is provided as the uppermost portion of the second preliminary stack PST2. Alternatively, the sacrificial layer GFL may be provided to cover the top surface of the first preliminary stack PST1 and the top surface of the second preliminary stack PST2, and in this case, the metal layer ML may be spaced apart from the top surface of the first preliminary stack PST1 and the top surface of the second preliminary stack PST2, with the sacrificial layer GFL interposed therebetween. The metal layer ML may be formed of or include at least one of, for example, nickel (Ni), palladium (Pd), cobalt (Co), aluminum (Al), or gold (Au). The metal layer ML may be a single metal layer or may be a plurality of metal layers. The formation of the metal layer ML may be performed using a deposition process or a sputtering process.

Referring to FIGS. 13 and 15, the metal layer ML of FIG. 14 may be partially removed. For example, the metal layer ML may be removed from the top surface of the substrate 100 exposed by the first trench TR1, the top surface of the sacrificial layer GFL, and the top surface of each of the first preliminary stacks PST1, and the top surface of each of the second preliminary stacks PST2. As a result, a portion of the metal layer ML may be left to cover the side surface of each of the first and second preliminary stacks PST1 and PST2 exposed by the first trench TR1. Next, the sacrificial layer GFL may be removed from the second and third trenches TR2 and TR3.

Referring to FIGS. 16, 17, and 18, a metal gathering layer MGL may be formed to fill the second and third trenches TR2 and TR3. The metal gathering layer MGL may be spaced apart from the metal layer ML in the first direction D1, with the first preliminary stack PST1 interposed therebetween. The metal gathering layer MGL may be spaced apart from the metal layer ML in the first direction D1, with the second preliminary stack PST2 interposed therebetween. The metal gathering layer MGL may have a high metal adsorption capacity, compared to the first and second amorphous semiconductor patterns ASP1 and ASP2. In addition, the metal gathering layer MGL may have a high metal adsorption capacity, compared to the first and second crystalline semiconductor patterns CSP1 and CSP2 to be described below. The metal gathering layer MGL may include silicon (Si), doped with at least one element of phosphorus (P), boron (B), arsenic (As), germanium (Ge), or carbon (C) at a concentration of 25 at% or lower. The metal gathering layer MGL may include at least one layer and may be, for example, a multi-layered structure. An annealing process using the metal layer ML as a catalyst may be performed to form the first and second crystalline semiconductor patterns CSP1 and CSP2 from the first and second amorphous semiconductor patterns ASP1 and ASP2, respectively. That is, the annealing process may be performed to crystallize an amorphous semiconductor material into a single-crystalline semiconductor material. The annealing process may be performed at a temperature of, for example, 400°C to 650°C. The crystallization process to the single-crystalline structure may be a metal-induced crystallization method (MILC). Metals MP may be diffused from the side surfaces of the first and second amorphous semiconductor patterns ASP1 and ASP2 in contact with the metal layer ML in the first direction D1 depicted by the arrow, and in this case, the first and second amorphous semiconductor patterns ASP1 and ASP2 may be crystallized to a single-crystalline structure by the metal-induced crystallization method. Substantially all metals MP may be transferred to the metal gathering layer MGL.

Referring to FIGS. 19, 20A, and 20B, the metal gathering layer MGL may be removed. Since the metal gathering layer MGL is removed, the top surface of the substrate 100 may be re-exposed through the second and third trenches TR2 and TR3. In an embodiment, metals, which may be present in the first trench TR1, may also be removed during the process of removing the metal gathering layer MGL.

According to a comparative example, a single-crystalline semiconductor pattern may be formed using an epitaxial growth process. The epitaxial growth process may take a long time to form a layer, may depend on the crystalline direction of the substrate, and may lack flexibility in adjusting the thickness or concentration of the deposited layers. By contrast, according to an embodiment of the present disclosure, a metal-induced crystallization method may be used to crystalize an amorphous semiconductor layer into crystalline semiconductor layer, and in this case, it may be possible to reduce the time required to form a layer, eliminate dependency on the crystalline direction of the substrate, and to adjust the thickness or concentration of the deposited layers with greater flexibility. In particular, when a plurality of layers, rather than a single layer, are formed, the difference between the two methods may be increased. In an embodiment, if the metal-induced crystallization method is used, first and second crystalline semiconductor patterns, which are spaced apart from each other in a second direction, may be formed to have different crystalline directions. In addition, the first crystalline semiconductor patterns, which are stacked in a third direction, may have different crystalline directions from each other. By using a metal gathering layer, it may be possible to effectively remove metals used in the metal-induced crystallization method. According to an embodiment of the present disclosure, metals may be transferred to the metal gathering layer through an annealing process. Since the metal gathering layer collects the metal elements, the metal elements, which may be present in the semiconductor pattern, may be effectively removed, before the process of forming a bit line and a data storage pattern. As a result, it may be possible to prevent an increase of the leakage current in a channel region and improve the reliability of the channel region. In the case where the metal gathering layer is not used, metal elements in the semiconductor pattern may be re-diffused to deteriorate the reliability of the three-dimensional semiconductor device.

Referring to FIGS. 21, 22A, and 22B, the first and second insulating patterns DP1 and DP2 may be removed. The thicknesses of the first and second crystalline semiconductor patterns CSP1 and CSP2 may be partially reduced during the process of removing the first and second insulating patterns DP1 and DP2. In an embodiment, the thicknesses of the first and second crystalline semiconductor patterns CSP1 and CSP2 may be reduced by an additional etching process or by a subsequent process of forming the gate dielectric layer Gox and preliminary gate conductive layers PGLa and PGLb. Since the first and second insulating patterns DP1 and DP2 are removed, first inner regions INR1 and second inner regions INR2 may be respectively formed between the first crystalline semiconductor patterns CSP1 and between the second crystalline semiconductor patterns CSP2, which are adjacent to each other in the third direction D3. The first inner region INR1 may be a region where the word line WL and the gapfill insulating pattern 110 will be formed, and the second inner region INR2 may be a region where the capping pattern CP will be formed. The first and second inner regions INR1 and INR2 may not be formed simultaneously but may be formed individually. A preliminary filling pattern PF may fill the second inner regions INR2. The preliminary filling pattern PF may include, for example, an insulating material. The gate dielectric layer Gox and the preliminary gate conductive layers PGLa and PGLb may be sequentially formed in the first inner regions INR1. The gate dielectric layer Gox and the preliminary gate conductive layers PGLa and PGLb may be formed to conformally cover a portion of the first crystalline semiconductor pattern CSP1 and a portion of the second crystalline semiconductor pattern CSP2. One of the gate dielectric layers Gox and one of the preliminary gate conductive layers PGLa and PGLb may be formed to cover and face a portion of each of the first crystalline semiconductor patterns CSP1, which are adjacent to each other in the second and third directions D2 and D3. Another gate dielectric layer Gox and another preliminary gate conductive layer PGLa and PGLb may be formed to cover and face a portion of each of the second crystalline semiconductor patterns CSP2, which are adjacent to each other in the second and third directions D2 and D3. Thereafter, the gapfill insulating pattern 110 may be formed in the first inner regions INR1. The bit lines BL may be formed to penetrate the gapfill insulating pattern 110 and to be in contact with side surfaces of the crystalline semiconductor patterns CSP. The bit lines BL may include the first bit lines BLa in contact with the first crystalline semiconductor patterns CSP1 and the second bit lines BLb in contact with the second crystalline semiconductor patterns CSP2.

Referring to FIGS. 23, 24A, and 24B, the preliminary filling pattern PF may be removed from a region on the substrate 100. The gate dielectric layer Gox and the preliminary gate conductive layers PGLa and PGLb may also be partially removed. Thus, each of the gate dielectric layers Gox may be divided into a plurality of gate dielectric layers Gox, which are adjacent to each other in the second and third directions D2 and D3. In addition, each of the preliminary gate conductive layers PGLa and PGLb may be divided into a plurality of gate electrodes GE1 and GE2, which are adjacent to each other in the second and third directions D1 and D3. The gate dielectric layers Gox may be provided to at least partially surround the first and second crystalline semiconductor patterns CSP1 and CSP2, which are some of the crystalline semiconductor patterns CSP. The gate electrodes GE1 and GE2 may be provided to at least partially surround the first and second crystalline semiconductor patterns CSP1 and CSP2, which are some of the crystalline semiconductor patterns CSP.

During the removal process, the second inner regions INR2 may be exposed to the outside. Due to the second inner regions INR2, side surfaces of the gate electrodes GE1 and GE2 may be exposed to the outside .

The gate electrodes GE1 and GE2 may include first gate electrodes GE1 at least partially surrounding the first crystalline semiconductor patterns CSP1 and second gate electrodes GE2 at least partially surrounding the second crystalline semiconductor patterns CSP2.

The gate dielectric layer Gox and the first gate electrode GE1 at least partially surrounding the first crystalline semiconductor pattern CSP1 may constitute the first word line WLa. The gate dielectric layer Gox and the second gate electrode GE2 at least partially surrounding the second crystalline semiconductor pattern CSP2 may constitute the second word line WLb.

A region of the first crystalline semiconductor pattern CSP1 at least partially surrounded by the first the word line WLa may constitute the channel region CH of the first crystalline semiconductor pattern CSP1. A region of the second crystalline semiconductor pattern CSP2 at least partially surrounded by the second word line WL2 may constitute the channel region CH of the second crystalline semiconductor pattern CSP2.

Referring to FIGS. 25 and 26, the capping pattern CP may be formed to fill the second inner region INR2, from which the preliminary filling pattern PF is removed. The capping pattern CP may include the first capping pattern CP1, which is provided to conformally cover the second inner regions INR2 and the second edge portions EA2 of the crystalline semiconductor patterns CSP, and the second capping pattern CP2, which is provided to fill a remaining portion of the second inner regions INR2 and surround the second edge portions EA2 of the crystalline semiconductor patterns CSP.

Thereafter, a fourth trench TR4 may be formed on the substrate 100 by removing a portion of the capping pattern CP. The fourth trench TR4 may be formed to extend in the second direction D2. Due to the fourth trench TR4, the second edge portions EA2 of the crystalline semiconductor patterns CSP may be exposed to the outside.

A removal process may be performed on the exposed portion of the second edge portions EA2 of the crystalline semiconductor patterns CSP through the fourth trench TR4. A portion of the first capping pattern CP1 may also be removed during the removal process.

The storage electrodes SE may be formed on the second edge portions EA2 of the crystalline semiconductor patterns CSP. In an embodiment, the formation of the storage electrodes SE may include forming silicide patterns on the second edge portions EA2 of the crystalline semiconductor patterns CSP and forming the storage electrodes SE through a SEG process using the silicide patterns as a seed layer.

Referring back to FIGS. 4 to 5B, a removal process may be performed on a portion of the second capping pattern CP2. Thus, the side surface of the second capping pattern CP2 may be aligned to the side surface of the second edge portion EA2 of the crystalline semiconductor pattern CSP. Thereafter, the capacitor dielectric layer CIL may be formed to conformally cover the storage electrodes SE. The plate electrode PE may be formed to fill a region between the storage electrodes SE and a remaining portion of the fourth trench TR4 described with reference to FIGS. 25 and 26. The storage electrode SE, the capacitor dielectric layer CIL, and the plate electrode PE may constitute the data storage pattern DSP. As a result, the first and second stacks ST1 and ST2 and the data storage pattern DSP may be formed, and here, each of the first and second stacks ST1 and ST2 may include the crystalline semiconductor patterns CSP, the word lines WL, the bit lines BL, the first capping patterns CP1, the second capping patterns CP2, and the gapfill insulating pattern 110. The cell array structure CS including the first and second stacks ST1 and ST2 and the data storage pattern DSP may be formed. Thereafter, the protection layer PL may be formed to cover the cell array structure CS.

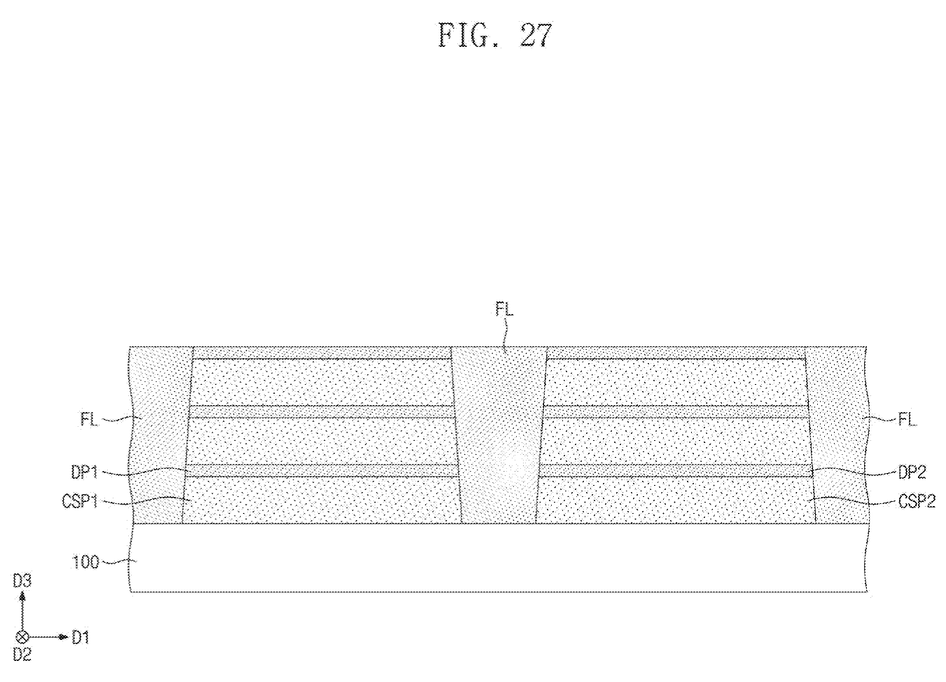

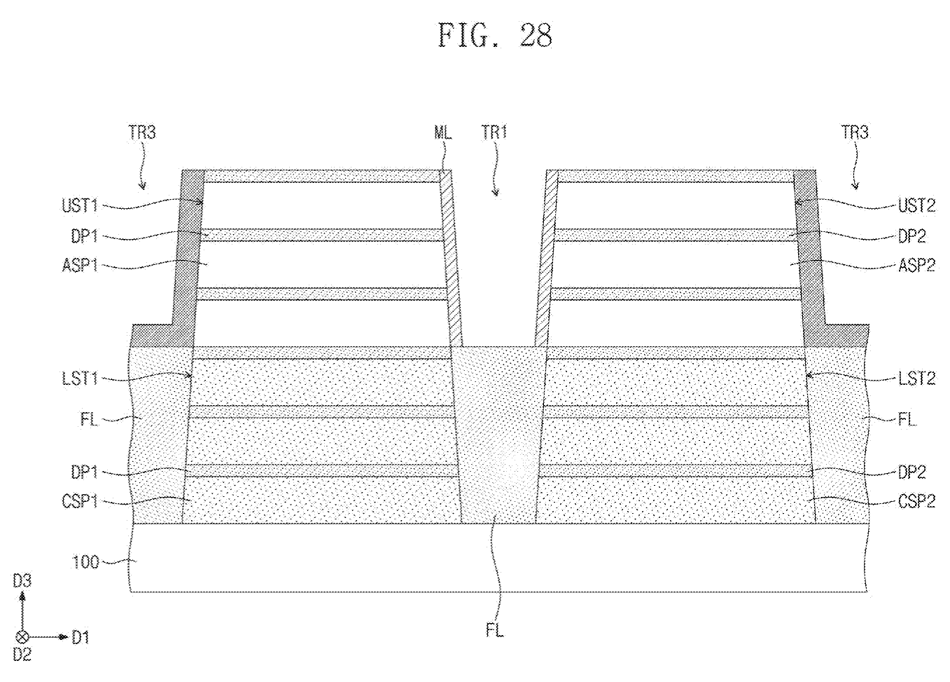

FIGS. 27 and 28 are cross-sectional views illustrating a method of fabricating a three-dimensional semiconductor device, according to an embodiment of the present disclosure.

A first lower preliminary stack LST1 and a second lower preliminary stack LST2 may be formed using the methods described with reference to FIGS. 7 to 20B. Each of the first and second lower preliminary stacks LST1 and LST2 may be formed by substantially the same method as that for the first and second preliminary stacks PST1 and PST2.

That is, the first lower preliminary stack LST1 may include the first crystalline semiconductor patterns CSP1 stacked, and the second lower preliminary stack LST2 may include the second crystalline semiconductor patterns CSP2 stacked. The first and second crystalline semiconductor patterns CSP1 and CSP2 may be formed through the metal-induced crystallization method.

A filling layer FL may be formed to expose top surfaces of the first and second lower preliminary stacks LST1 and LST2 and fill a region therebetween. In an embodiment, the filling layer FL may include the same or similar material as the sacrificial layer GFL or the preliminary filling pattern PF described above.

Referring to FIG. 28, a first upper preliminary stack UST1 may be formed on the first lower preliminary stack LST1, and a second upper preliminary stack UST2 may be formed on the second lower preliminary stack LST2. As described with reference to FIGS. 7 to 10B, the formation of the first and second upper preliminary stacks UST1 and UST2 may include alternately forming the amorphous semiconductor layer AL and the insulating layer DL and forming the first to third trenches TR1 to TR3. As described with reference to FIGS. 13 to 18, the metal layer ML may be formed on side surfaces of the first and second upper preliminary stacks UST1 and UST2, and the metal gathering layer MGL may be formed on opposite side surfaces of the first and second upper preliminary stacks UST1 and UST2. Next, the crystalline semiconductor patterns CSP may be formed through the metal-induced crystallization method. The preliminary stack CST of FIGS. 19 to 20B may be formed by removing the filling layer FL. A subsequent process may be performed through the methods described with reference to FIGS. 21 to 20B. After the removal of the filling layer FL, the three-dimensional semiconductor device of FIGS. 3 to 5B may be formed using the method as described with reference to FIGS. 21 to 26.

At least one of the components, elements, modules, units, or the like (collectively "components" in this paragraph) represented by a block or an equivalent indication (collectively “block”) in the above embodiments, including the drawings such as FIGS. 1, 2A, 2B and 2C, for example, the row decoder, control logic, sense amp, column decode, or the like, may carry out the above-described function or functions. These blocks may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

According to an embodiment of the present disclosure, single-crystalline semiconductor layers may be formed from amorphous semiconductor layers through a metal-induced crystallization method. As a result, a three-dimensional semiconductor device may include crystalline semiconductor patterns, which are effectively formed regardless of the crystalline direction of a substrate. In addition, a metal gathering layer may be provided to effectively remove a metallic material, which is used in the metal-induced crystallization method. As a result, it may be possible to increase the reliability of a channel region and improve the reliability of the three-dimensional semiconductor device.

While example embodiments of the present disclosure have been particularly shown and described, it will be understood by one of ordinary skill in the art that variations in form and detail may be made therein without departing from the spirit and scope of the attached claims.

What is claimed is:

1. A three-dimensional semiconductor device comprising:
a first crystalline semiconductor pattern on a substrate and a second crystalline semiconductor pattern on the first crystalline semiconductor pattern, wherein each of the first crystalline semiconductor pattern and the second crystalline semiconductor pattern extends in a first direction parallel to a top surface of the substrate;
a first word line on the first crystalline semiconductor pattern and a second word line on the second crystalline semiconductor pattern, wherein each of the first word line and the second word line extends in a second direction parallel to the top surface of the substrate and orthogonal to the first direction; and
a bit line on a side surface of each of the first crystalline semiconductor pattern and the second crystalline semiconductor pattern, the bit line extending in a third direction perpendicular to the top surface of the substrate,
wherein a crystalline direction of the first crystalline semiconductor pattern is different from a crystalline direction of the second crystalline semiconductor pattern.

2. The three-dimensional semiconductor device of claim 1, wherein each of the first crystalline semiconductor pattern and the second crystalline semiconductor pattern has a single-crystalline structure.

3. The three-dimensional semiconductor device of claim 1, wherein each of the first crystalline semiconductor pattern and the second crystalline semiconductor pattern comprises a same semiconductor material.

4. The three-dimensional semiconductor device of claim 1, wherein each of the first crystalline semiconductor pattern and the second crystalline semiconductor pattern comprises single-crystalline silicon.

5. The three-dimensional semiconductor device of claim 1, further comprising a data storage pattern on a second side surface of each of the first crystalline semiconductor pattern and the second crystalline semiconductor pattern.

6. The three-dimensional semiconductor device of claim 1, wherein the first crystalline semiconductor pattern is in contact with the top surface of the substrate.

7. A three-dimensional semiconductor device comprising:
a substrate; and
a cell array structure on the substrate,
wherein the cell array structure comprises:
a plurality of crystalline semiconductor patterns arranged vertically on the substrate, wherein each crystalline semiconductor pattern of the plurality of crystalline semiconductor patterns extends in a first direction parallel to a top surface of the substrate;
a plurality of word lines on the plurality of crystalline semiconductor patterns and extending in a second direction parallel to the top surface of the substrate and orthogonal to the first direction; and
a bit line on first side surfaces of the plurality of crystalline semiconductor patterns, wherein the bit line extends in a third direction perpendicular to the top surface of the substrate,
wherein the plurality of crystalline semiconductor patterns comprises a single-crystalline semiconductor material,
wherein the substrate comprises a semiconductor substrate or an insulating substrate,
wherein the semiconductor substrate is one of a single-crystalline semiconductor substrate, a polycrystalline semiconductor substrate, or an amorphous semiconductor substrate, and
wherein a crystalline direction of the single-crystalline semiconductor substrate is different from a crystalline direction of the plurality of crystalline semiconductor patterns.

8. The three-dimensional semiconductor device of claim 7, wherein a lowermost one of the plurality of crystalline semiconductor patterns is in contact with the top surface of the substrate.

9. The three-dimensional semiconductor device of claim 7, further comprising a peripheral circuit structure between the substrate and the cell array structure,
wherein the peripheral circuit structure comprises:
a peripheral semiconductor substrate; and
an insulating structure on the peripheral semiconductor substrate.

10. The three-dimensional semiconductor device of claim 7, further comprising a data storage pattern on second side surfaces of the plurality of crystalline semiconductor patterns,
wherein each crystalline semiconductor pattern of the plurality of crystalline semiconductor patterns comprises a first edge portion and a second edge portion which are spaced apart from each other in the first direction, and a channel region therebetween,
wherein the plurality of word lines are on respective channel regions of the plurality of crystalline semiconductor patterns,
wherein, for each crystalline semiconductor pattern of the plurality of crystalline semiconductor patterns, the first side of the crystalline semiconductor pattern is a side surface of the first edge portion of the crystalline semiconductor pattern, and
wherein, for each crystalline semiconductor pattern of the plurality of crystalline semiconductor patterns, the second side of the crystalline semiconductor pattern is a side surface of the second edge portion of the crystalline semiconductor pattern.

11. The three-dimensional semiconductor device of claim 10, wherein the channel region of each crystalline semiconductor pattern of the plurality of crystalline semiconductor patterns comprises a substantially metal-free region.

12. The three-dimensional semiconductor device of claim 11, wherein a metal concentration of the channel region of each crystalline semiconductor pattern of the plurality of crystalline semiconductor patterns is equal to or lower than 100 ppm.

13. A three-dimensional semiconductor device comprising:
a substrate;
a first stack and a second stack e on the substrate, wherein the first stack and the second stack are adjacent to each other in a first direction parallel to a top surface of the substrate; and
a data storage pattern between the first stack and the second stack,
wherein the first stack comprises:
a first crystalline semiconductor pattern on the substrate and extending in the first direction;
a first word line on the first crystalline semiconductor pattern and extending in a second direction parallel to the top surface of the substrate and orthogonal to the first direction; and
a first bit line on a first side surface of the first crystalline semiconductor pattern, the first bit line extending in a third direction perpendicular to the top surface of the substrate,
wherein the second stack comprises a second crystalline semiconductor pattern extending in the first direction,
wherein the first crystalline semiconductor pattern and the second crystalline semiconductor pattern are spaced apart from each other in the first direction, and
wherein a crystalline direction of the first crystalline semiconductor pattern is different from a crystalline direction of the second crystalline semiconductor pattern.

14. The three-dimensional semiconductor device of claim 13, wherein each of the first crystalline semiconductor pattern and the second crystalline semiconductor pattern has a single-crystalline structure.

15. The three-dimensional semiconductor device of claim 13, wherein each of the first crystalline semiconductor pattern and the second crystalline semiconductor pattern comprises a same semiconductor material.

16. The three-dimensional semiconductor device of claim 13, wherein the second stack further comprises:
a second word line on the second crystalline semiconductor pattern and extending in the second direction; and
a second bit line extending in the third direction along a first side surface of the second crystalline semiconductor pattern.

17. The three-dimensional semiconductor device of claim 13, wherein the first stack further comprises a plurality of first crystalline semiconductor patterns including the first crystalline semiconductor pattern,
wherein the second stack further comprises a plurality of second crystalline semiconductor patterns including the second crystalline semiconductor pattern,
wherein the plurality of first crystalline semiconductor patterns are spaced apart from each other in the third direction, and
wherein the plurality of second crystalline semiconductor patterns are spaced apart from each other in the third direction.

18. The three-dimensional semiconductor device of claim 17, wherein among the plurality of first crystalline semiconductor patterns, first crystalline semiconductor patterns which are adjacent to one another in the third direction have different crystalline directions.

19. The three-dimensional semiconductor device of claim 13, wherein the substrate comprises a semiconductor substrate or an insulating substrate,
wherein the semiconductor substrate is one of a single-crystalline semiconductor substrate, a polycrystalline semiconductor substrate, or an amorphous semiconductor substrate, and
wherein a crystalline direction of the single-crystalline semiconductor substrate is different from a crystalline direction of the first crystalline semiconductor pattern and the second crystalline semiconductor pattern.

20. The three-dimensional semiconductor device of claim 13, wherein the first crystalline semiconductor pattern comprises a first edge portion and a second edge portion which are spaced apart from each other in the first direction, and a channel region therebetween,
wherein the first word line is on the channel region,
wherein the first side of the first crystalline semiconductor pattern is a side surface of the first edge portion, and
wherein a side surface of the second edge portion is in contact with the data storage pattern.
